(19) United States
(12) Patent Application Publication
(10) Pub. No.: US 2025/0373210 A1
(43) Pub. Date: Dec. 4, 2025

(54) APPARATUS AND METHODS FOR POWER AMPLIFIER LOAD MISMATCH COMPENSATION

(71) Applicant: Skyworks Solutions, Inc., Irvine, CA (US)

(72) Inventor: Neal J. Tuffy, Dublin (IE)

(21) Appl. No.: 19/208,400

(22) Filed: May 14, 2025

Related U.S. Application Data
(60) Provisional application No. 63/652,877, filed on May 29, 2024.
(60) Provisional application No. 63/652,811, filed on May 29, 2024.

(51) Int. Cl. H03F 1/56; H03F 3/24

(52) U.S. Cl. CPC H03F 1/565; H03F 3/245; H03F 2200/387; H03F 2200/421; H03F 2200/451

(57) ABSTRACT

Apparatus and methods for load mismatch compensation of power amplifiers are disclosed. In certain embodiments, a power amplifier system includes a power amplifier having an output coupled to an antenna through a mismatch compensation circuit. The mismatch compensation circuit includes a bank of switchable shunt capacitors and a bank of switchable series capacitors, with the bank of switchable series capacitors connected between the output of the power amplifier and the bank of switchable shunt capacitors.

### CROSS-REFERENCE TO RELATED APPLICATIONS

This application claims the benefit of priority under 35 U.S.C. § 119 of U.S. Provisional Patent Application No. 63/652,877, filed May 29, 2024 and titled “APPARATUS AND METHODS FOR POWER AMPLIFIER LOAD MISMATCH COMPENSATION,” and of U.S. Provisional Patent Application No. 63/652,811, filed May 29, 2024 and titled “LOAD MISMATCH COMPENSATION OF POWER AMPLIFIERS,” each of which is herein incorporated by reference in its entirety.

### BACKGROUND

### Technical Field

Embodiments of the invention relate to electronic systems, and in particular, to radio frequency (RF) electronics.

### Description of Related Technology

RF communication systems can be used for transmitting and/or receiving signals of a wide range of frequencies. For example, an RF communication system can be used to wirelessly communicate RF signals in a frequency range of about 30 kHz to 300 GHz, such as in the range of about 410 MHz to about 7.125 GHz for Fifth Generation (5G) cellular communications in Frequency Range 1 (FR1) or in the range of about 24.250 GHz to about 71.000 GHz for Frequency Range 2 (FR2) of the 5G communication standard.

Examples of RF communication systems include, but are not limited to, mobile phones, tablets, base stations, network access points, customer-premises equipment (CPE), laptops, and wearable electronics.

### SUMMARY

In certain embodiments, the present disclosure relates to a power amplifier system including a power amplifier having an input configured to receive a radio frequency input signal and an output configured to provide a radio frequency output signal, an antenna terminal configured to electrically connect to an antenna, and a mismatch compensation circuit electrically connected along a radio frequency signal path from the output of the power amplifier to the antenna terminal. The mismatch compensation circuit includes a bank of switchable shunt capacitors and a bank of switchable series capacitors that is electrically connected between the output of the power amplifier and the bank of switchable shunt capacitors.

In some embodiments, the bank of switchable series capacitors includes a first circuit branch in parallel with a second circuit branch between the output of the power amplifier and the antenna terminal, the first circuit branch including a first capacitor in series with a first switch and the second circuit branch including a second capacitor in series with a second switch. According to a number of embodiments, the bank of switchable shunt capacitors includes a third circuit branch and a fourth circuit branch each connected between the radio frequency signal path and a ground voltage, the third circuit branch including a third capacitor in series with a third switch and the fourth circuit branch including a fourth capacitor in series with a fourth switch. In accordance with several embodiments, the bank of switchable shunt capacitors further includes a fifth circuit branch electrically connected between the radio frequency signal path and the ground voltage and a sixth circuit branch electrically connected between the radio frequency signal path and the ground voltage, the third circuit branch including a fifth capacitor in series with a fifth switch and the sixth circuit branch including a sixth capacitor in series with a sixth switch. According to various embodiments, the bank of switchable series capacitors further includes a capacitor in parallel with the first circuit branch and the second circuit branch. In accordance with a number of embodiments, the bank of switchable series capacitors further includes an inductor parallel with the first circuit branch and the second circuit branch.

In several embodiments, the power amplifier system further includes a first output matching network electrically connected between the output of the power amplifier and the bank of switchable series capacitors. According to various embodiments, the first output matching network includes an output connected to the bank of switchable series capacitors and a series inductor at the output.

In some embodiments, the mismatch compensation circuit further includes an inductor electrically connected between the bank of switchable series capacitors and the bank of switchable shunt capacitors.

In certain embodiments, the present disclosure relates to a mobile device. The mobile device includes an antenna and a front-end system including a power amplifier configured to receive a radio frequency input signal at an input and to provide a radio frequency output signal at an output. The front-end system further includes a mismatch compensation circuit electrically connected along a radio frequency signal path from the output of the power amplifier to the antenna, the mismatch compensation circuit including a bank of switchable shunt capacitors and a bank of switchable series capacitors that is electrically connected between the output of the power amplifier and the bank of switchable shunt capacitors.

In various embodiments, the bank of switchable series capacitors includes a first circuit branch in parallel with a second circuit branch between the output of the power amplifier and the antenna, the first circuit branch including a first capacitor in series with a first switch and the second circuit branch including a second capacitor in series with a second switch. According to a number of embodiments, the bank of switchable shunt capacitors includes a third circuit branch and a fourth circuit branch each connected between the radio frequency signal path and a ground voltage, the third circuit branch including a third capacitor in series with a third switch and the fourth circuit branch including a fourth capacitor in series with a fourth switch. In accordance with several embodiments, the bank of switchable shunt capacitors further includes a fifth circuit branch electrically connected between the radio frequency signal path and the ground voltage and a sixth circuit branch electrically connected between the radio frequency signal path and the ground voltage, the fifth circuit branch including a fifth capacitor in series with a fifth switch and the sixth circuit branch including a sixth capacitor in series with a sixth switch. According to some embodiments, the bank of switchable series capacitors further includes a capacitor in parallel with the first circuit branch and the second circuit branch. In accordance with a number of embodiments, the bank of switchable series capacitors further includes an inductor parallel with the first circuit branch and the second circuit branch.

In several embodiments, the front-end system further includes a first output matching network electrically connected between the output of the power amplifier and the bank of switchable series capacitors. According to various embodiments, the first output matching network includes an output connected to the bank of switchable series capacitors and a series inductor at the output.

In some embodiments, the mismatch compensation circuit further includes an inductor electrically connected between the bank of switchable series capacitors and the bank of switchable shunt capacitors.

In certain embodiments, the present disclosure relates to a packaged module. The packaged module includes a package substrate, and one or more semiconductor dies attached to the package substrate. The one or more semiconductor dies include a power amplifier configured to receive a radio frequency input signal at an input and to provide a radio frequency output signal at an output, the one or more semiconductor dies further including a mismatch compensation circuit electrically connected along a radio frequency signal path from the output of the power amplifier to an antenna terminal, the mismatch compensation circuit including a bank of switchable shunt capacitors and a bank of switchable series capacitors that is electrically connected between the output of the power amplifier and the bank of switchable shunt capacitors.

In some embodiments, the bank of switchable series capacitors includes a first circuit branch in parallel with a second circuit branch between the output of the power amplifier and the antenna terminal, the first circuit branch including a first capacitor in series with a first switch and the second circuit branch including a second capacitor in series with a second switch. According to a number of embodiments, the bank of switchable shunt capacitors includes a third circuit branch and a fourth circuit branch each connected between the radio frequency signal path and a ground voltage, the third circuit branch including a third capacitor in series with a third switch and the fourth circuit branch including a fourth capacitor in series with a fourth switch. In accordance with several embodiments, the bank of switchable shunt capacitors further includes a fifth circuit branch electrically connected between the radio frequency signal path and the ground voltage, the fifth circuit branch including a fifth capacitor in series with a fifth switch. According to various embodiments, the bank of switchable shunt capacitors further includes a sixth circuit branch electrically connected between the radio frequency signal path and the ground voltage, the sixth circuit branch including a sixth capacitor in series with a sixth switch. In accordance with a number of embodiments, the bank of switchable series capacitors further includes a capacitor in parallel with the first circuit branch and the second circuit branch. According to several embodiments, the bank of switchable series capacitors further includes an inductor parallel with the first circuit branch and the second circuit branch.

In various embodiments, the one or more semiconductor dies further includes a first output matching network electrically connected between the output of the power amplifier and the bank of switchable series capacitors. According to several embodiments, the first output matching network includes an output connected to the bank of switchable series capacitors and a series inductor at the output.

In some embodiments, the mismatch compensation circuit further includes an inductor electrically connected between the bank of switchable series capacitors and the bank of switchable shunt capacitors.

In certain embodiments, a method of power amplifier load mismatch compensation is disclosed. The method includes providing a radio frequency output signal from an output of a power amplifier to an antenna through a mismatch compensation circuit that includes a bank of switchable shunt capacitors and a bank of switchable series capacitors, detecting an output load mismatch at the output of the power amplifier using a mismatch detection circuit, generating a plurality of switch settings based on the output load mismatch using the mismatch detection circuit, and controlling the bank of switchable shunt capacitors and the bank of switchable series capacitors using the plurality of switch settings to compensate for the output load mismatch.

In various embodiments, the method further includes sensing a voltage standing wave ratio at the output of the power amplifier using a directional coupler and the mismatch detection circuit.

In several embodiments, the bank of switchable series capacitors includes a first circuit branch in parallel with a second circuit branch between the output of the power amplifier and the antenna, the first circuit branch including a first capacitor in series with a first switch and the second circuit branch including a second capacitor in series with a second switch. According to a number of embodiments, the bank of switchable shunt capacitors includes a third circuit branch and a fourth circuit branch each connected between the radio frequency signal path and a ground voltage, the third circuit branch including a third capacitor in series with a third switch and the fourth circuit branch including a fourth capacitor in series with a fourth switch. In accordance with various embodiments, the bank of switchable shunt capacitors further includes a fifth circuit branch electrically connected between the radio frequency signal path and the ground voltage, the fifth circuit branch including a fifth capacitor in series with a fifth switch. According to some embodiments, the bank of switchable shunt capacitors further includes a sixth circuit branch electrically connected between the radio frequency signal path and the ground voltage, the sixth circuit branch including a sixth capacitor in series with a sixth switch. In accordance with a number of embodiments, the bank of switchable series capacitors further includes at least one of a capacitor or an inductor in parallel with the first circuit branch and the second circuit branch.

In some embodiments, a first output matching network is electrically connected between the output of the power amplifier and the bank of switchable series capacitors. According to a number of embodiments, the first output matching network includes an output connected to the bank of switchable series capacitors and a series inductor at the output.

In various embodiments, the mismatch compensation circuit further includes an inductor electrically connected between the bank of switchable series capacitors and the bank of switchable shunt capacitors.

In certain embodiments, a power amplifier system is provided. The power amplifier system includes a power amplifier including an output configured to provide a radio frequency output signal to an antenna terminal. The power amplifier system further includes a mismatch compensation circuit electrically connected between the output of the power amplifier and the antenna terminal, the mismatch compensation circuit including a bank of switchable shunt capacitors and a bank of switchable series capacitors. The power amplifier system further includes a mismatch detection circuit configured to detect an output load mismatch at the output of the power amplifier and to generate a plurality of switch settings based on the output load mismatch, the plurality of switch settings operable to control the bank of switchable shunt capacitors and the bank of switchable series capacitors to compensate for the output load mismatch.

In some embodiments, the power amplifier system further includes a directional coupler configured to couple a sensed radio frequency signal from the output of the power amplifier to the mismatch detection circuit.

In several embodiments, the bank of switchable series capacitors includes a first circuit branch in parallel with a second circuit branch between the output of the power amplifier and the antenna terminal, the first circuit branch including a first capacitor in series with a first switch and the second circuit branch including a second capacitor in series with a second switch. According to a number of embodiments, the bank of switchable shunt capacitors includes a third circuit branch and a fourth circuit branch each connected between the radio frequency signal path and a ground voltage, the third circuit branch including a third capacitor in series with a third switch and the fourth circuit branch including a fourth capacitor in series with a fourth switch. In accordance with some embodiments, the bank of switchable shunt capacitors further includes a fifth circuit branch electrically connected between the radio frequency signal path and the ground voltage, the fifth circuit branch including a fifth capacitor in series with a fifth switch. According to various embodiments, the bank of switchable shunt capacitors further includes a sixth circuit branch electrically connected between the radio frequency signal path and the ground voltage, the sixth circuit branch including a sixth capacitor in series with a sixth switch. In accordance with a number of embodiments, the bank of switchable series capacitors further includes at least one of a capacitor or an inductor in parallel with the first circuit branch and the second circuit branch.

In various embodiments, the power amplifier system further includes a first output matching network electrically connected between the output of the power amplifier and the bank of switchable series capacitors. According to a number of embodiments, the first output matching network includes an output connected to the bank of switchable series capacitors and a series inductor at the output. In accordance with several embodiments, the mismatch compensation circuit further includes an inductor electrically connected between the bank of switchable series capacitors and the bank of switchable shunt capacitors.

In certain embodiments, the present disclosure relates to a mobile device. The mobile device includes an antenna and a front-end system including a mismatch compensation circuit that includes a bank of switchable shunt capacitors and a bank of switchable series capacitors, a mismatch detection circuit, and a power amplifier including an output configured to provide a radio frequency output signal to the antenna through the mismatch compensation circuit. The mismatch detection circuit is configured to detect an output load mismatch at the output of the power amplifier and to generate a plurality of switch settings based on the output load mismatch, the plurality of switch settings operable to control the bank of switchable shunt capacitors and the bank of switchable series capacitors to compensate for the output load mismatch.

In some embodiments, the front-end system further includes a directional coupler configured to couple a sensed radio frequency signal from the output of the power amplifier to the mismatch detection circuit.

In various embodiments, the bank of switchable series capacitors includes a first circuit branch in parallel with a second circuit branch between the output of the power amplifier and the antenna, the first circuit branch including a first capacitor in series with a first switch and the second circuit branch including a second capacitor in series with a second switch. According to a number of embodiments, the bank of switchable shunt capacitors includes a third circuit branch and a fourth circuit branch each connected between the radio frequency signal path and a ground voltage, the third circuit branch including a third capacitor in series with a third switch and the fourth circuit branch including a fourth capacitor in series with a fourth switch. In accordance with several embodiments, the bank of switchable shunt capacitors further includes a fifth circuit branch electrically connected between the radio frequency signal path and the ground voltage, the fifth circuit branch including a fifth capacitor in series with a fifth switch. According to some embodiments, the bank of switchable shunt capacitors further includes a sixth circuit branch electrically connected between the radio frequency signal path and the ground voltage, the sixth circuit branch including a sixth capacitor in series with a sixth switch. In accordance with several embodiments, the bank of switchable series capacitors further includes at least one of a capacitor or an inductor in parallel with the first circuit branch and the second circuit branch.

In various embodiments, the mobile device further includes a first output matching network electrically connected between the output of the power amplifier and the bank of switchable series capacitors. According to a number of embodiments, the first output matching network includes an output connected to the bank of switchable series capacitors and a series inductor at the output.

In some embodiments, the mismatch compensation circuit further includes an inductor electrically connected between the bank of switchable series capacitors and the bank of switchable shunt capacitors.

### BRIEF DESCRIPTION OF THE DRAWINGS

Embodiments of this disclosure will now be described, by way of non-limiting example, with reference to the accompanying drawings.

FIG. 1 is a schematic diagram of one example of a communication network.

FIG. 2A is a schematic diagram of one example of a communication link using carrier aggregation.

FIG. 2B illustrates various examples of uplink carrier aggregation for the communication link of FIG. 2A.

FIG. 2C illustrates various examples of downlink carrier aggregation for the communication link of FIG. 2A.

FIG. 3A is a schematic diagram of one example of a downlink channel using multi-input and multi-output (MIMO) communications.

FIG. 3B is schematic diagram of one example of an uplink channel using MIMO communications.

FIG. 3C is schematic diagram of another example of an uplink channel using MIMO communications.

FIG. 4A is a schematic diagram of one example of a communication system that operates with beamforming.

FIG. 4B is a schematic diagram of one example of beamforming to provide a transmit beam.

FIG. 4C is a schematic diagram of one example of beamforming to provide a receive beam.

FIG. 5 is a schematic diagram of one embodiment of a power amplifier system with load mismatch compensation.

FIG. 6 is a schematic diagram of another embodiment of a power amplifier system with load mismatch compensation.

FIG. 7A is a schematic diagram of another embodiment of a power amplifier system with load mismatch compensation.

FIG. 7B is a schematic diagram of another embodiment of a power amplifier system with load mismatch compensation.

FIG. 7C is a schematic diagram of another embodiment of a power amplifier system with load mismatch compensation.

FIG. 7D is a schematic diagram of another embodiment of a power amplifier system with load mismatch compensation.

FIG. 8 is a graph of plots of error vector magnitude (EVM) versus output power for various examples of power amplifier load mismatch.

FIG. 9 is a schematic diagram of another embodiment of a power amplifier system with load mismatch compensation.

FIG. 10A is a table of one example of mismatch compensation settings for the power amplifier system of FIG. 9 for 3:1 variation in voltage standing wave ratio (VSWR).

FIG. 10B is a table of one example of mismatch compensation settings for the power amplifier system of FIG. 9 for 2:1 variation in VSWR.

FIG. 10C is a Smith chart depicting example impedances at a collector of a bipolar transistor of a power amplifier for 3:1 variation in VSWR with and without mismatch compensation.

FIG. 10D is a graph of one example of EVM versus output power for one example of 2:1 variation in VSWR without mismatch compensation.

FIG. 10E is a graph of one example of EVM versus output power for one example of 2:1 variation in VSWR with mismatch compensation.

FIG. 10F is a graph of one example of EVM versus output power for one example of 3:1 variation in VSWR without mismatch compensation.

FIG. 10G is a graph of one example of EVM versus output power for one example of 3:1 variation in VSWR with mismatch compensation.

FIG. 10H is a graph of EVM versus VSWR phase at 17 dBm output power with and without mismatch compensation.

FIG. 10I is a graph of EVM versus VSWR phase at 19 dBm output power with and without mismatch compensation.

FIG. 10J is a graph of one example of EVM improvement from mismatch compensation versus output power.

FIG. 10K is a graph of one example of collector current of a bipolar transistor of a power amplifier versus output power for 2:1 variation in VSWR with and without mismatch compensation.

FIG. 10L is a graph of one example of collector current of a bipolar transistor of a power amplifier versus output power for 3:1 variation in VSWR with and without mismatch compensation.

FIG. 10M is a graph of one example of collector current savings from mismatch compensation versus output power for 2:1 and 3:1 variation in VSWR.

FIG. 11 is a schematic diagram of one embodiment of a mobile device.

FIG. 12 is a schematic diagram of a power amplifier system according to one embodiment.

FIG. 13A is a schematic diagram of one embodiment of a packaged module.

FIG. 13B is a schematic diagram of a cross-section of the packaged module of FIG. 13A taken along the lines 13B-13B.

### DETAILED DESCRIPTION OF CERTAIN EMBODIMENTS

The following detailed description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

The International Telecommunication Union (ITU) is a specialized agency of the United Nations (UN) responsible for global issues concerning information and communication technologies, including the shared global use of radio spectrum.

The 3rd Generation Partnership Project (3GPP) is a collaboration between groups of telecommunications standard bodies across the world, such as the Association of Radio Industries and Businesses (ARIB), the Telecommunications Technology Committee (TTC), the China Communications Standards Association (CCSA), the Alliance for Telecommunications Industry Solutions (ATIS), the Telecommunications Technology Association (TTA), the European Telecommunications Standards Institute (ETSI), and the Telecommunications Standards Development Society, India (TSDSI).

Working within the scope of the ITU, 3GPP develops and maintains technical specifications for a variety of mobile communication technologies, including, for example, second generation (2G) technology (for instance, Global System for Mobile Communications (GSM) and Enhanced Data Rates for GSM Evolution (EDGE)), third generation (3G) technology (for instance, Universal Mobile Telecommunications System (UMTS) and High Speed Packet Access (HSPA)), and fourth generation (4G) technology (for instance, Long Term Evolution (LTE) and LTE-Advanced).

The technical specifications controlled by 3GPP can be expanded and revised by specification releases, which can span multiple years and specify a breadth of new features and evolutions.

In one example, 3GPP introduced carrier aggregation (CA) for LTE in Release 10. Although initially introduced with two downlink carriers, 3GPP expanded carrier aggregation in Release 14 to include up to five downlink carriers and up to three uplink carriers. Other examples of new features and evolutions provided by 3GPP releases include, but are not limited to, License Assisted Access (LAA), enhanced LAA (cLAA), Narrowband Internet of things (NB-IoT), Vehicle-to-Everything (V2X), and High Power User Equipment (HPUE).

3GPP introduced Phase 1 of fifth generation (5G) technology in Release 15 and introduced Phase 2 of 5G technology in Release 16. Subsequent 3GPP releases will further evolve and expand 5G technology. 5G technology is also referred to herein as 5G New Radio (NR).

5G NR supports or plans to support a variety of features, such as communications over millimeter wave spectrum, beamforming capability, high spectral efficiency waveforms, low latency communications, multiple radio numerology, and/or non-orthogonal multiple access (NOMA). Although such RF functionalities offer flexibility to networks and enhance user data rates, supporting such features can pose a number of technical challenges.

The teachings herein are applicable to a wide variety of communication systems, including, but not limited to, communication systems using advanced cellular technologies, such as LTE-Advanced, LTE-Advanced Pro, and/or 5G NR.

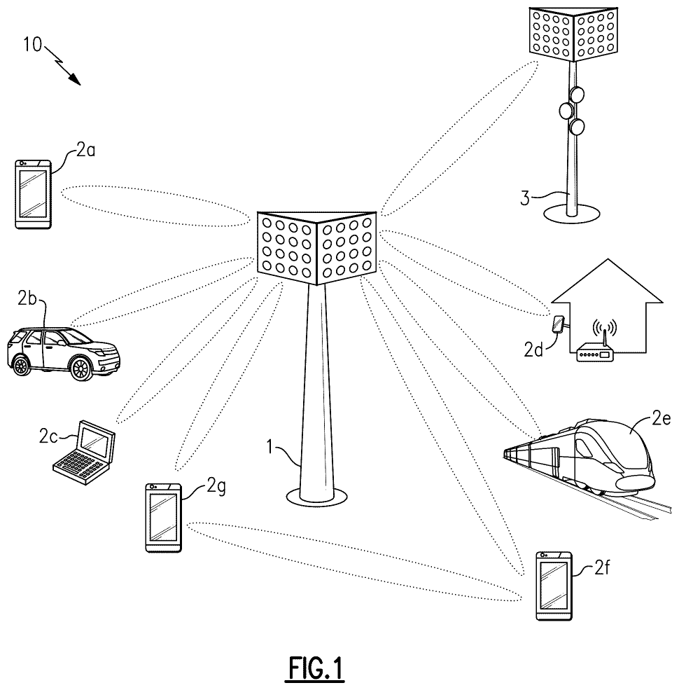

FIG. 1 is a schematic diagram of one example of a communication network 10. The communication network 10 includes a macro cell base station 1, a small cell base station 3, and various examples of user equipment (UE), including a first mobile device 2a, a wireless-connected car 2b, a laptop 2c, a stationary wireless device 2d, a wireless-connected train 2e, a second mobile device 2f, and a third mobile device 2g.

Although specific examples of base stations and user equipment are illustrated in FIG. 1, a communication network can include base stations and user equipment of a wide variety of types and/or numbers.

For instance, in the example shown, the communication network 10 includes the macro cell base station 1 and the small cell base station 3. The small cell base station 3 can operate with relatively lower power, shorter range, and/or with fewer concurrent users relative to the macro cell base station 1. The small cell base station 3 can also be referred to as a femtocell, a picocell, or a microcell. Although the communication network 10 is illustrated as including two base stations, the communication network 10 can be implemented to include more or fewer base stations and/or base stations of other types.

Although various examples of user equipment are shown, the teachings herein are applicable to a wide variety of user equipment, including, but not limited to, mobile phones, tablets, laptops, IoT devices, wearable electronics, customer premises equipment (CPE), wireless-connected vehicles, wireless relays, and/or a wide variety of other communication devices. Furthermore, user equipment includes not only currently available communication devices that operate in a cellular network, but also subsequently developed communication devices that will be readily implementable with the inventive systems, processes, methods, and devices as described and claimed herein.

The illustrated communication network 10 of FIG. 1 supports communications using a variety of cellular technologies, including, for example, 4G LTE and 5G NR. In certain implementations, the communication network 10 is further adapted to provide a wireless local area network (WLAN), such as WiFi. Although various examples of communication technologies have been provided, the communication network 10 can be adapted to support a wide variety of communication technologies.

Various communication links of the communication network 10 have been depicted in FIG. 1. The communication links can be duplexed in a wide variety of ways, including, for example, using frequency-division duplexing (FDD) and/or time-division duplexing (TDD). FDD is a type of radio frequency communications that uses different frequencies for transmitting and receiving signals. FDD can provide a number of advantages, such as high data rates and low latency. In contrast, TDD is a type of radio frequency communications that uses about the same frequency for transmitting and receiving signals, and in which transmit and receive communications are switched in time. TDD can provide a number of advantages, such as efficient use of spectrum and variable allocation of throughput between transmit and receive directions.

In certain implementations, user equipment can communicate with a base station using one or more of 4G LTE, 5G NR, and WiFi technologies. In certain implementations, enhanced license assisted access (eLAA) is used to aggregate one or more licensed frequency carriers (for instance, licensed 4G LTE and/or 5G NR frequencies), with one or more unlicensed carriers (for instance, unlicensed WiFi frequencies).

As shown in FIG. 1, the communication links include not only communication links between UE and base stations, but also UE to UE communications and base station to base station communications. For example, the communication network 10 can be implemented to support self-fronthaul and/or self-backhaul (for instance, as between mobile device 2g and mobile device 2f).

The communication links can operate over a wide variety of frequencies. In certain implementations, communications are supported using 5G NR technology over one or more frequency bands that are less than 6 Gigahertz (GHz) and/or over one or more frequency bands that are greater than 6 GHz. For example, the communication links can serve Frequency Range 1 (FR1), Frequency Range 2 (FR2), or a combination thereof. In one embodiment, one or more of the mobile devices support a HPUE power class specification.

In certain implementations, a base station and/or user equipment communicates using beamforming. For example, beamforming can be used to focus signal strength to overcome path losses, such as high loss associated with communicating over high signal frequencies. In certain embodiments, user equipment, such as one or more mobile phones, communicate using beamforming on millimeter wave frequency bands in the range of 30 GHz to 300 GHz and/or upper centimeter wave frequencies in the range of 6 GHz to 30 GHz, or more particularly, 24 GHz to 30 GHz. Cellular user equipment can communicate using beamforming and/or other techniques over a wide range of frequencies, including, for example, FR2-1 (24 GHz to 52 GHz), FR2-2 (52 GHz to 71 GHz), and/or FR1 (400 MHz to 7125 MHz).

Different users of the communication network 10 can share available network resources, such as available frequency spectrum, in a wide variety of ways.

In one example, frequency division multiple access (FDMA) is used to divide a frequency band into multiple frequency carriers. Additionally, one or more carriers are allocated to a particular user. Examples of FDMA include, but are not limited to, single carrier FDMA (SC-FDMA) and orthogonal FDMA (OFDMA). OFDMA is a multicarrier technology that subdivides the available bandwidth into multiple mutually orthogonal narrowband subcarriers, which can be separately assigned to different users.

Other examples of shared access include, but are not limited to, time division multiple access (TDMA) in which a user is allocated particular time slots for using a frequency resource, code division multiple access (CDMA) in which a frequency resource is shared amongst different users by assigning each user a unique code, space-divisional multiple access (SDMA) in which beamforming is used to provide shared access by spatial division, and non-orthogonal multiple access (NOMA) in which the power domain is used for multiple access. For example, NOMA can be used to serve multiple users at the same frequency, time, and/or code, but with different power levels.

Enhanced mobile broadband (eMBB) refers to technology for growing system capacity of LTE networks. For example, eMBB can refer to communications with a peak data rate of at least 10 Gbps and a minimum of 100 Mbps for each user. Ultra-reliable low latency communications (uRLLC) refers to technology for communication with very low latency, for instance, less than 2 milliseconds. uRLLC can be used for mission-critical communications such as for autonomous driving and/or remote surgery applications. Massive machine-type communications (mMTC) refers to low cost and low data rate communications associated with wireless connections to everyday objects, such as those associated with Internet of Things (IoT) applications.

The communication network 10 of FIG. 1 can be used to support a wide variety of advanced communication features, including, but not limited to, eMBB, uRLLC, and/or mMTC.

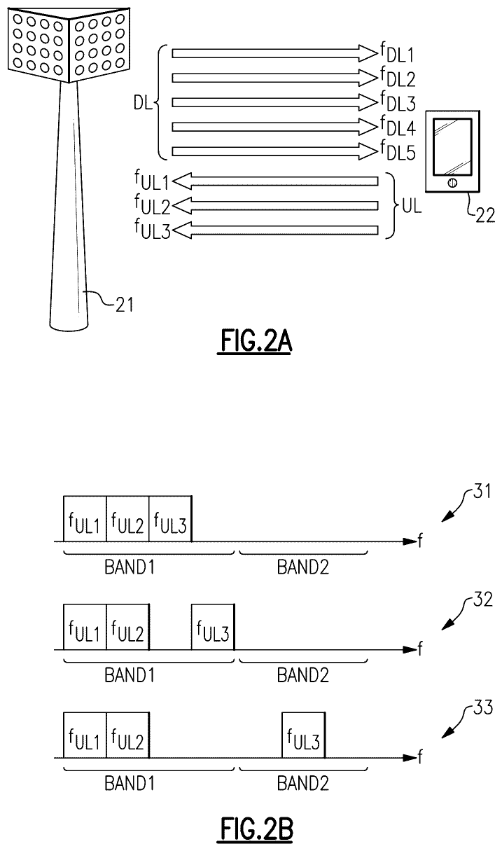

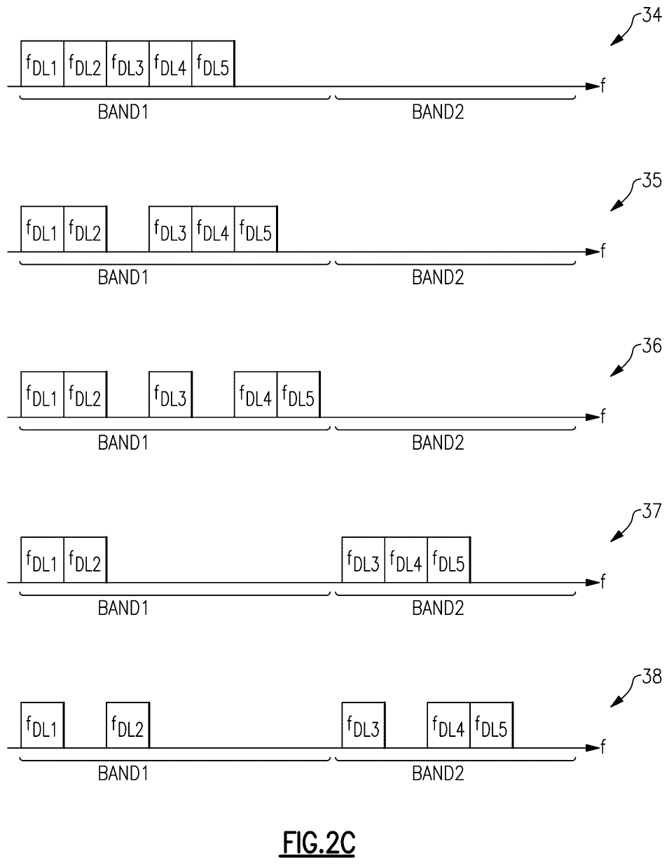

FIG. 2A is a schematic diagram of one example of a communication link using carrier aggregation. Carrier aggregation can be used to widen bandwidth of the communication link by supporting communications over multiple frequency carriers, thereby increasing user data rates and enhancing network capacity by utilizing fragmented spectrum allocations.

In the illustrated example, the communication link is provided between a base station 21 and a mobile device 22. As shown in FIG. 2A, the communications link includes a downlink channel used for RF communications from the base station 21 to the mobile device 22, and an uplink channel used for RF communications from the mobile device 22 to the base station 21.

Although FIG. 2A illustrates carrier aggregation in the context of FDD communications, carrier aggregation can also be used for TDD communications.

In certain implementations, a communication link can provide asymmetrical data rates for a downlink channel and an uplink channel. For example, a communication link can be used to support a relatively high downlink data rate to enable high speed streaming of multimedia content to a mobile device, while providing a relatively slower data rate for uploading data from the mobile device to the cloud.

In the illustrated example, the base station 21 and the mobile device 22 communicate via carrier aggregation, which can be used to selectively increase bandwidth of the communication link. Carrier aggregation includes contiguous aggregation, in which contiguous carriers within the same operating frequency band are aggregated. Carrier aggregation can also be non-contiguous, and can include carriers separated in frequency within a common band or in different bands.

In the example shown in FIG. 2A, the uplink channel includes three aggregated component carriers f_{UL1}, f_{UL2}, and f_{UL3}. Additionally, the downlink channel includes five aggregated component carriers f_{DL1}, f_{DL2}, f_{DL3}, f_{DL4}, and f_{DL5}. Although one example of component carrier aggregation is shown, more or fewer carriers can be aggregated for uplink and/or downlink. Moreover, a number of aggregated carriers can be varied over time to achieve desired uplink and downlink data rates.

For example, a number of aggregated carriers for uplink and/or downlink communications with respect to a particular mobile device can change over time. For example, the number of aggregated carriers can change as the device moves through the communication network and/or as network usage changes over time.

FIG. 2B illustrates various examples of uplink carrier aggregation for the communication link of FIG. 2A. FIG. 2B includes a first carrier aggregation scenario 31, a second carrier aggregation scenario 32, and a third carrier aggregation scenario 33, which schematically depict three types of carrier aggregation.

The carrier aggregation scenarios 31-33 illustrate different spectrum allocations for a first component carrier f_{UL1}, a second component carrier f_{UL2}, and a third component carrier f_{UL3}. Although FIG. 2B is illustrated in the context of aggregating three component carriers, carrier aggregation can be used to aggregate more or fewer carriers. Moreover, although illustrated in the context of uplink, the aggregation scenarios are also applicable to downlink.

The first carrier aggregation scenario 31 illustrates intra-band contiguous carrier aggregation, in which component carriers that are adjacent in frequency and in a common frequency band are aggregated. For example, the first carrier aggregation scenario 31 depicts aggregation of component carriers f_{UL1}, f_{UL2}, and f_{UL3} that are contiguous and located within a first frequency band BAND1.

With continuing reference to FIG. 2B, the second carrier aggregation scenario 32 illustrates intra-band non-continuous carrier aggregation, in which two or more components carriers that are non-adjacent in frequency and within a common frequency band are aggregated. For example, the second carrier aggregation scenario 32 depicts aggregation of component carriers f_{UL1}, f_{UL2}, and f_{UL3} that are non-contiguous, but located within a first frequency band BAND1.

The third carrier aggregation scenario 33 illustrates inter-band non-contiguous carrier aggregation, in which component carriers that are non-adjacent in frequency and in multiple frequency bands are aggregated. For example, the third carrier aggregation scenario 33 depicts aggregation of component carriers f_{UL1} and f_{UL2} of a first frequency band BAND1 with component carrier f_{UL3} of a second frequency band BAND2.

FIG. 2C illustrates various examples of downlink carrier aggregation for the communication link of FIG. 2A. The examples depict various carrier aggregation scenarios 34-38 for different spectrum allocations of a first component carrier f_{DL1}, a second component carrier f_{DL2}, a third component carrier f_{DL3}, a fourth component carrier f_{DL4}, and a fifth component carrier f_{DL5}. Although FIG. 2C is illustrated in the context of aggregating five component carriers, carrier aggregation can be used to aggregate more or fewer carriers. Moreover, although illustrated in the context of downlink, the aggregation scenarios are also applicable to uplink.

The first carrier aggregation scenario 34 depicts aggregation of component carriers that are contiguous and located within the same frequency band. Additionally, the second carrier aggregation scenario 35 and the third carrier aggregation scenario 36 illustrates two examples of aggregation that are non-contiguous, but located within the same frequency band. Furthermore, the fourth carrier aggregation scenario 37 and the fifth carrier aggregation scenario 38 illustrates two examples of aggregation in which component carriers that are non-adjacent in frequency and in multiple frequency bands are aggregated. As a number of aggregated component carriers increases, a complexity of possible carrier aggregation scenarios also increases.

With reference to FIGS. 2A-2C, the individual component carriers used in carrier aggregation can be of a variety of frequencies, including, for example, frequency carriers in the same band or in multiple bands. Additionally, carrier aggregation is applicable to implementations in which the individual component carriers are of about the same bandwidth as well as to implementations in which the individual component carriers have different bandwidths.

Certain communication networks allocate a particular user device with a primary component carrier (PCC) or anchor carrier for uplink and a PCC for downlink. Additionally, when the mobile device communicates using a single frequency carrier for uplink or downlink, the user device communicates using the PCC. To enhance bandwidth for uplink communications, the uplink PCC can be aggregated with one or more uplink secondary component carriers (SCCs). Additionally, to enhance bandwidth for downlink communications, the downlink PCC can be aggregated with one or more downlink SCCs.

In certain implementations, a communication network provides a network cell for each component carrier. Additionally, a primary cell can operate using a PCC, while a secondary cell can operate using a SCC. The primary and secondary cells may have different coverage areas, for instance, due to differences in frequencies of carriers and/or network environment.

License assisted access (LAA) refers to downlink carrier aggregation in which a licensed frequency carrier associated with a mobile operator is aggregated with a frequency carrier in unlicensed spectrum, such as WiFi. LAA employs a downlink PCC in the licensed spectrum that carries control and signaling information associated with the communication link, while unlicensed spectrum is aggregated for wider downlink bandwidth when available. LAA can operate with dynamic adjustment of secondary carriers to avoid WiFi users and/or to coexist with WiFi users. Enhanced license assisted access (eLAA) refers to an evolution of LAA that aggregates licensed and unlicensed spectrum for both downlink and uplink. Furthermore, NR-U can operate on top of LAA/eLAA over a 5 GHz band (5150 to 5925 MHz) and/or a 6 GHz band (5925 MHz to 7125 MHz).

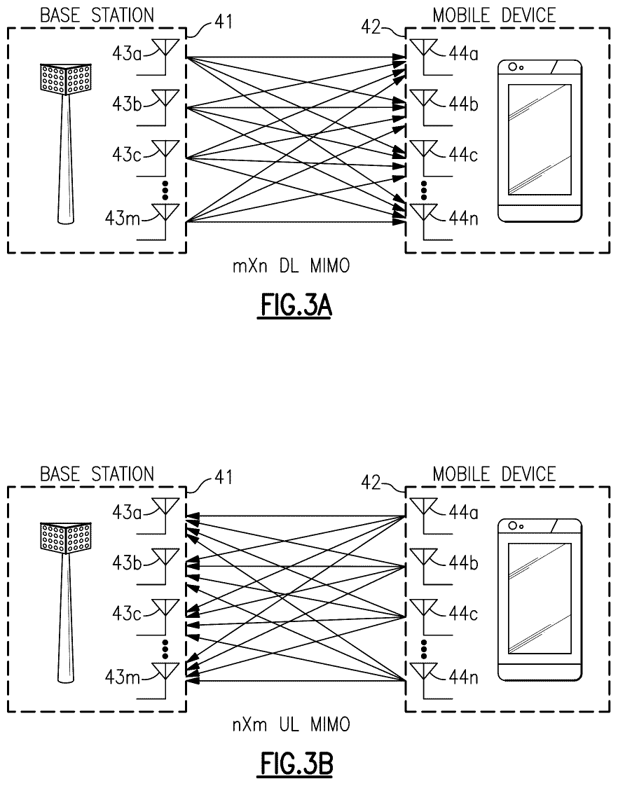

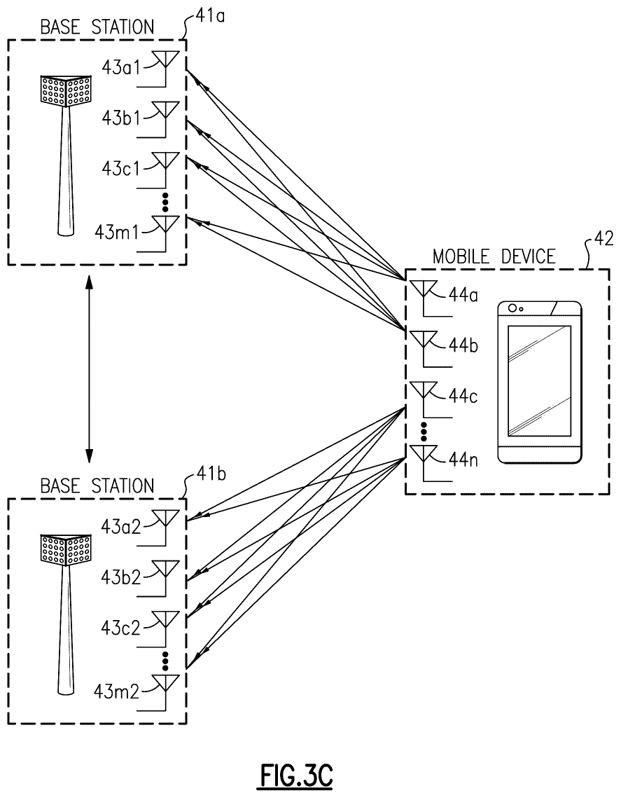

FIG. 3A is a schematic diagram of one example of a downlink channel using multi-input and multi-output (MIMO) communications. FIG. 3B is schematic diagram of one example of an uplink channel using MIMO communications.

MIMO communications use multiple antennas for simultaneously communicating multiple data streams over common frequency spectrum. In certain implementations, the data streams operate with different reference signals to enhance data reception at the receiver. MIMO communications benefit from higher SNR, improved coding, and/or reduced signal interference due to spatial multiplexing differences of the radio environment.

MIMO order refers to a number of separate data streams sent or received. For instance, MIMO order for downlink communications can be described by a number of transmit antennas of a base station and a number of receive antennas for UE, such as a mobile device. For example, two-by-two (2×2) DL MIMO refers to MIMO downlink communications using two base station antennas and two UE antennas. Additionally, four-by-four (4×4) DL MIMO refers to MIMO downlink communications using four base station antennas and four UE antennas.

In the example shown in FIG. 3A, downlink MIMO communications are provided by transmitting using M antennas 43a, 43b, 43c, . . . 43m of the base station 41 and receiving using N antennas 44a, 44b, 44c, . . . 44n of the mobile device 42. Accordingly, FIG. 3A illustrates an example of m×n DL MIMO.

Likewise, MIMO order for uplink communications can be described by a number of transmit antennas of UE, such as a mobile device, and a number of receive antennas of a base station. For example, 2×2 UL MIMO refers to MIMO uplink communications using two UE antennas and two base station antennas. Additionally, 4×4 UL MIMO refers to MIMO uplink communications using four UE antennas and four base station antennas.

In the example shown in FIG. 3B, uplink MIMO communications are provided by transmitting using N antennas 44a, 44b, 44c, . . . 44n of the mobile device 42 and receiving using M antennas 43a, 43b, 43c, . . . 43m of the base station 41. Accordingly, FIG. 3B illustrates an example of n×m UL MIMO.

By increasing the level or order of MIMO, bandwidth of an uplink channel and/or a downlink channel can be increased.

MIMO communications are applicable to communication links of a variety of types, such as FDD communication links and TDD communication links.

FIG. 3C is schematic diagram of another example of an uplink channel using MIMO communications. In the example shown in FIG. 3C, uplink MIMO communications are provided by transmitting using N antennas 44a, 44b, 44c, . . . 44n of the mobile device 42. Additional a first portion of the uplink transmissions are received using M antennas 43a1, 43b1, 43c1, . . . 43m1 of a first base station 41a, while a second portion of the uplink transmissions are received using M antennas 43a2, 43b2, 43c2, . . . 43m2 of a second base station 41b. Additionally, the first base station 41a and the second base station 41b communication with one another over wired, optical, and/or wireless links.

The MIMO scenario of FIG. 3C illustrates an example in which multiple base stations cooperate to facilitate MIMO communications.

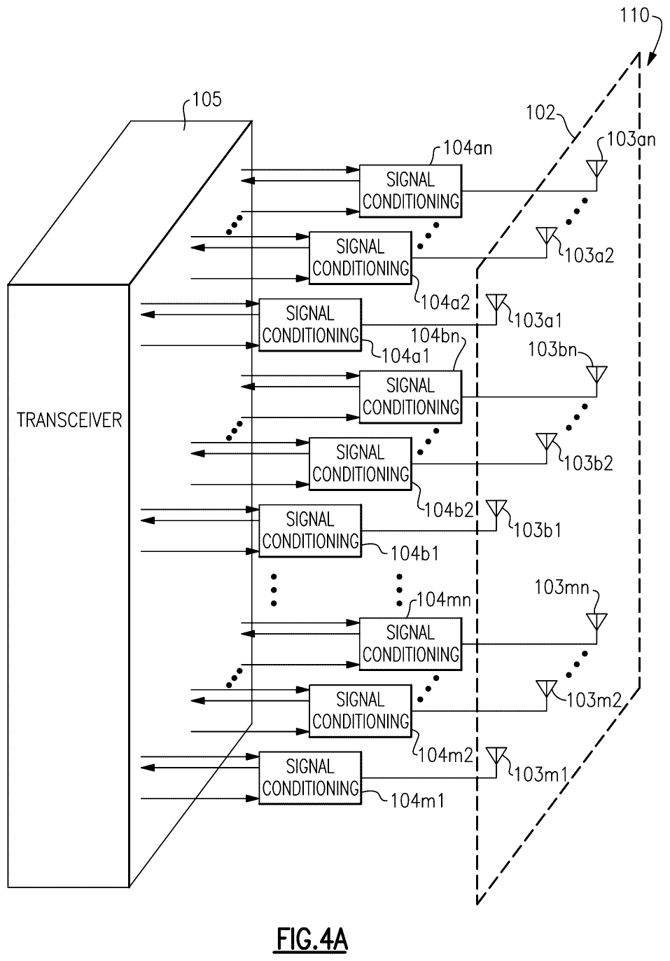

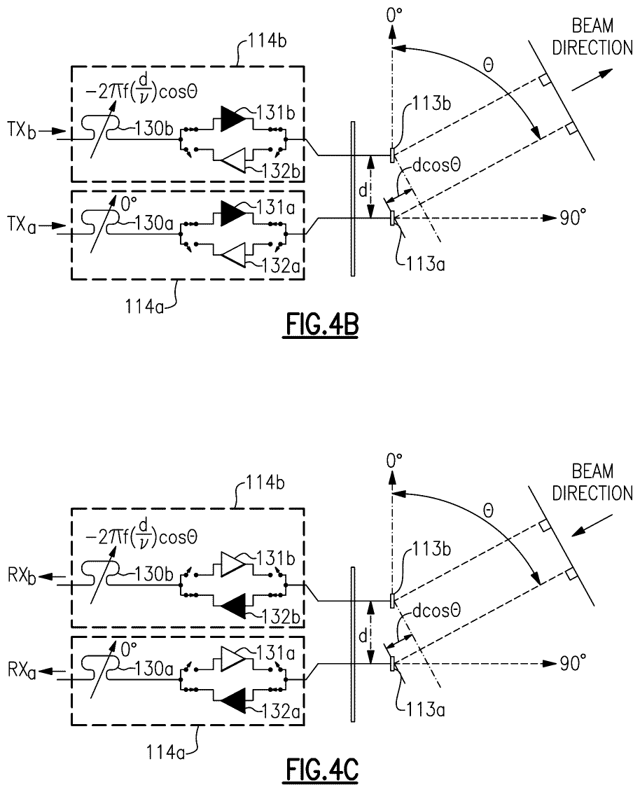

FIG. 4A is a schematic diagram of one example of a communication system 110 that operates with beamforming. The communication system 110 includes a transceiver 105, signal conditioning circuits 104a1, 104a2 . . . 104an, 104b1, 104b2 . . . 104bn, 104m1, 104m2 . . . 104mn, and an antenna array 102 that includes antenna elements 103a1, 103a2 . . . 103an, 103b1, 103b2 . . . 103bn, 103m1, 103m2 . . . 103mn.

Communications systems that communicate using millimeter wave carriers (for instance, 30 GHz to 300 GHz), centimeter wave carriers (for instance, 3 GHz to 30 GHz), and/or other frequency carriers can employ an antenna array to provide beam formation and directivity for transmission and/or reception of signals.

For example, in the illustrated embodiment, the communication system 110 includes an array 102 of m×n antenna elements, which are each controlled by a separate signal conditioning circuit, in this embodiment. As indicated by the ellipses, the communication system 110 can be implemented with any suitable number of antenna elements and signal conditioning circuits.

With respect to signal transmission, the signal conditioning circuits can provide transmit signals to the antenna array 102 such that signals radiated from the antenna elements combine using constructive and destructive interference to generate an aggregate transmit signal exhibiting beam-like qualities with more signal strength propagating in a given direction away from the antenna array 102.

In the context of signal reception, the signal conditioning circuits process the received signals (for instance, by separately controlling received signal phases) such that more signal energy is received when the signal is arriving at the antenna array 102 from a particular direction. Accordingly, the communication system 110 also provides directivity for reception of signals.

The relative concentration of signal energy into a transmit beam or a receive beam can be enhanced by increasing the size of the array. For example, with more signal energy focused into a transmit beam, the signal is able to propagate for a longer range while providing sufficient signal level for RF communications. For instance, a signal with a large proportion of signal energy focused into the transmit beam can exhibit high effective isotropic radiated power (EIRP).

In the illustrated embodiment, the transceiver 105 provides transmit signals to the signal conditioning circuits and processes signals received from the signal conditioning circuits. As shown in FIG. 4A, the transceiver 105 generates control signals for the signal conditioning circuits. The control signals can be used for a variety of functions, such as controlling the gain and phase of transmitted and/or received signals to control beamforming.

FIG. 4B is a schematic diagram of one example of beamforming to provide a transmit beam. FIG. 4B illustrates a portion of a communication system including a first signal conditioning circuit 114a, a second signal conditioning circuit 114b, a first antenna element 113a, and a second antenna element 113b.

Although illustrated as included two antenna elements and two signal conditioning circuits, a communication system can include additional antenna elements and/or signal conditioning circuits. For example, FIG. 4B illustrates one embodiment of a portion of the communication system 110 of FIG. 4A.

The first signal conditioning circuit 114a includes a first phase shifter 130a, a first power amplifier 131a, a first low noise amplifier (LNA) 132a, and switches for controlling selection of the power amplifier 131a or LNA 132a. Additionally, the second signal conditioning circuit 114b includes a second phase shifter 130b, a second power amplifier 131b, a second LNA 132b, and switches for controlling selection of the power amplifier 131b or LNA 132b.

Although one embodiment of signal conditioning circuits is shown, other implementations of signal conditioning circuits are possible. For instance, in one example, a signal conditioning circuit includes one or more band filters, duplexers, and/or other components.

In the illustrated embodiment, the first antenna element 113a and the second antenna element 113b are separated by a distance d. Additionally, FIG. 4B has been annotated with an angle θ, which in this example has a value of about 90° when the transmit beam direction is substantially perpendicular to a plane of the antenna array and a value of about 0° when the transmit beam direction is substantially parallel to the plane of the antenna array.

By controlling the relative phase of the transmit signals provided to the antenna elements 113a, 113b, a desired transmit beam angle θ can be achieved. For example, when the first phase shifter 130a has a reference value of 0°, the second phase shifter 130b can be controlled to provide a phase shift of about −2πf(d/ν)cos θ radians, where f is the fundamental frequency of the transmit signal, d is the distance between the antenna elements, ν is the velocity of the radiated wave, and x is the mathematic constant pi.

In certain implementations, the distance d is implemented to be about ½λ, where λ is the wavelength of the fundamental component of the transmit signal. In such implementations, the second phase shifter 130b can be controlled to provide a phase shift of about −π cos θ radians to achieve a transmit beam angle θ.

Accordingly, the relative phase of the phase shifters 130a, 130b can be controlled to provide transmit beamforming. In certain implementations, a baseband processor and/or a transceiver (for example, the transceiver 105 of FIG. 4A) controls phase values of one or more phase shifters and gain values of one or more controllable amplifiers to control beamforming.

FIG. 4C is a schematic diagram of one example of beamforming to provide a receive beam. FIG. 4C is similar to FIG. 4B, except that FIG. 4C illustrates beamforming in the context of a receive beam rather than a transmit beam.

As shown in FIG. 4C, a relative phase difference between the first phase shifter 130a and the second phase shifter 130b can be selected to about equal to −2πf(d/ν)cos θ radians to achieve a desired receive beam angle θ. In implementations in which the distance d corresponds to about ½λ, the phase difference can be selected to about equal to −π cos θ radians to achieve a receive beam angle θ.

Although various equations for phase values to provide beamforming have been provided, other phase selection values are possible, such as phase values selected based on implementation of an antenna array, implementation of signal conditioning circuits, and/or a radio environment.

### Examples of Load Mismatch Compensation for Power Amplifiers

Apparatus and methods for load mismatch compensation of power amplifiers are disclosed. In certain embodiments, a power amplifier system includes a power amplifier having an output coupled to an antenna through a mismatch compensation circuit. The mismatch compensation circuit includes a bank of switchable shunt capacitors and a bank of switchable series capacitors, with the bank of switchable series capacitors connected between the output of the power amplifier and the bank of switchable shunt capacitors.

The switch settings of the capacitor banks are selectable to provide load mismatch compensation to the power amplifier. For example, the switch settings can be used to compensate for a 2:1 variation in VSWR, a 3:1 variation in VSWR, or another suitable power amplifier mismatch.

In certain implementations, the bank of switchable series capacitors includes a parallel combination of two or more series circuit branches along the RF signal path from the output of the power amplifier to the antenna. Each of the series branches includes a capacitor in series with a switch. In one example, exactly two series branches (each including a capacitor in series with a switch) are included in the bank of switchable series capacitors. In another example, exactly three series branches are each included in the bank. In some implementations, a capacitor or an inductor is included in parallel to the series branches.

The power amplifier system can further include a first output matching network between the output of the power amplifier and the bank of switchable series capacitors. The first output matching network can include various components, such as series inductor(s), shunt inductor(s), series capacitor(s), shunt capacitor(s), series inductor-capacitor (LC) circuits, shunt LC circuit, and/or other components for providing output matching to the power amplifier. The first output matching network can also serve to provide terminations at desired frequencies (including, but not limited to, second harmonic and/or third harmonic frequencies) and/or to provide a power amplifier supply voltage to the power amplifier (for instance, a choke inductor can be integrated into the first output matching network).

When the first output matching network is included, the mismatch compensation circuit can also serve as a second output matching network that operates in combination with the first output matching network to provide output matching.

In certain implementations, a series inductor is included along the signal path between the output of the power amplifier and the bank of switchable shunt capacitors. In a first example, a series inductor is included at the output of the first output matching network. In a second example, a series inductor is included in parallel to the circuit branches of the bank of switchable series capacitors. In a third example, a series inductor is included between the bank of switchable series capacitors and the bank of switchable shunt capacitors.

The bank of switchable shunt capacitors can include two or more shunt circuit branches between the RF signal path and ground that each include a capacitor in series with a switch. In one example, exactly three shunt branches (each including a capacitor in series with a switch between the RF signal path and ground) are included in the bank of switchable shunt capacitors. In another example, exactly four shunt branches are each included in the bank.

The capacitor banks can be implemented with capacitors of any suitable capacitance values desired for a particular application and/or power amplifier design. Additionally, the capacitors can have capacitance values that are weighted in accordance with any desired weighting scheme, including both uniform and non-uniform weightings.

In certain implementations, the power amplifier system further includes circuitry for detecting a power amplifier load mismatch (for instance, a VSWR) and setting the switch settings of the capacitor banks to compensate for the load mismatch. For example, the power amplifier system can include a directional coupler for generating a sensed RF signal from the output of the power amplifier and a mismatch detection circuit (for example, a VSWR detection circuit) for detecting an amount of load mismatch present at the output of the power amplifier. Additionally, the mismatch detection circuit generates a control signal that sets the switch settings for the switchable series capacitor bank and the switchable shunt capacitors bank to compensate for the load mismatch.

FIG. 5 is a schematic diagram of one embodiment of a power amplifier system 220 with load mismatch compensation. The power amplifier system 220 includes a power amplifier 201, a directional coupler 202, a first output matching network 203, a mismatch compensation circuit 204 (which also serves as a second output matching network), an antenna 205, and a mismatch detection circuit 206.

The power amplifier 201 receives an RF input signal RF_{IN} at an input and provides an RF output signal RF_{OUT} at an output. The power amplifier 201 amplifies the RF input signal RF_{IN} based on a desired amplification level or amount. The power amplifier 201 can be implemented using any desired amplifier topology including, but not limited to, a common emitter bipolar transistor amplifier (using, for instance, a heterojunction bipolar transistor or HBT for providing amplification), a cascode bipolar transistor amplifier, a common source field-effect transistor (FET) amplifier, or a cascode FET amplifier.

With continuing reference to FIG. 5, the power amplifier 201 provides the RF output signal RF_{OUT} to the antenna 205 along an RF signal path that includes the directional coupler 202, the first output matching network 203, and the mismatch compensation circuit 204. Although certain components are shown, the RF signal path can be modified to include more or fewer components as desired. In one example, filters, switches, antenna-plexers, and/or other front-end components are included between the mismatch compensation circuit 204 and the antenna 205.

As shown in FIG. 5, the mismatch compensation circuit 204 includes a bank of switchable series capacitors 207 and a bank of switchable shunt capacitors 208. The bank of switchable series capacitors 207 is connected between the first output matching network 203 and the bank of switchable shunt capacitors 208. The bank of switchable series capacitors 207 includes two or more circuit branches in parallel with one another along the RF signal path (and thus are in series with respect to the RF signal path). Each circuit branch includes a capacitor and a switch in series. The bank of switchable shunt capacitors 208 includes two or more circuit branches in parallel with one another between the RF signal path and a ground voltage (and thus are in shunt with respect to the RF signal path). Each circuit branch includes a capacitor and a switch in series.

In the illustrated embodiment, the directional coupler 202 senses the output of the power amplifier 201 to generate a sensed RF signal that is provided to the mismatch detection circuit 206. The mismatch detection circuit 206 uses the sensed RF signal (or other suitable detection signal) to detect an output load mismatch of the power amplifier 201, such as a VSWR. The mismatch detection circuit 206 generates a control signal CTL based on the detected output load mismatch and uses the control signal CTL to set the switch settings of the capacitor banks 207/208. The switch settings are set to compensate for the output load mismatch.

In certain implementations, the mismatch detection circuit 206 iteratively adjusts the switch settings until the detected output load mismatch is less than an error threshold.

Any of the power amplifier systems herein can be implemented with circuitry for detecting power amplifier output load mismatch and for controlling the switch settings of capacitors banks to compensate for the output load mismatch.

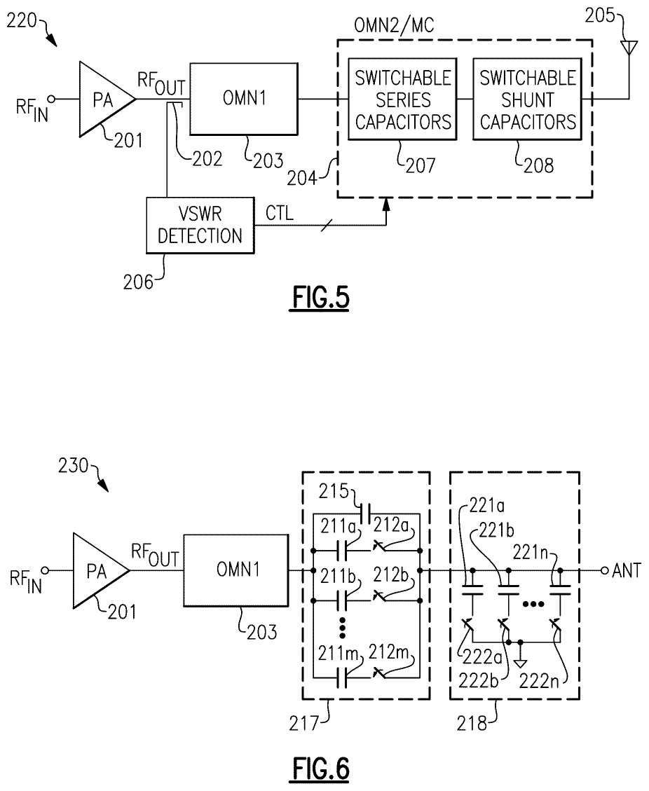

FIG. 6 is a schematic diagram of another embodiment of a power amplifier system 230 with load mismatch compensation. The power amplifier system 230 includes a power amplifier 201, a first output matching network 203, and a mismatch compensation circuit/second output matching network that includes a bank of switchable series capacitors 217 and a bank of switchable shunt capacitors 218.

As shown in FIG. 6, the power amplifier 201 amplifies an RF input signal RF_{IN} to generate an RF output signal RF_{OUT} that is provided to an antenna along an RF signal path that includes the first output matching network 203, the bank of switchable series capacitors 217, and the bank of switchable shunt capacitors 218. Although not shown in FIG. 6, the power amplifier system 230 can be implemented to include circuitry for detecting output load mismatch of the power amplifier 201 and for controlling the switch settings of the capacitors banks 217/218 to compensate for the output load mismatch.

In the illustrated embodiment, the bank of switchable series capacitors 207 includes a fixed capacitor 215 in parallel with m circuit branches, where m is an integer greater than or equal to 2. In one example, m is exactly 2. In another example, m is exactly 3. In yet another example, m is exactly 4.

Although shown as including the fixed capacitor 215, the fixed capacitor 215 can be omitted. For example, in some implementations, the fixed capacitor 215 is omitted in favor of including an inductor.

The m circuit branches include capacitors 211a, 211b, . . . 211m and switches 212a, 212b, . . . 212m. Each of the capacitors 211a, 211b, . . . 211m are in series with a corresponding one of the switches 212a, 212b, . . . 212m. Each of the switches 212a, 212b, . . . 212m is individually controllable (for instance, using the mismatch compensation circuit 206 of FIG. 5) to control the capacitance of the bank 217.

With continuing reference to FIG. 6, the bank of switchable shunt capacitors 218 includes n circuit branches in parallel between the RF signal path and ground, where n is an integer greater than or equal to 2. In a first example, n is exactly 2. In a second example, n is exactly 3. In a third example, n is exactly 4. In a fourth example, n is exactly 5.

The n circuit branches include capacitors 212a, 221b, . . . 221n and switches 222a, 222b, . . . 222n. Each of the capacitors 221a, 221b, . . . 221n are in series with a corresponding one of the switches 222a, 222b, . . . 222n. Each of the switches 222a, 222b, . . . 222n is individually controllable (for instance, using the mismatch compensation circuit 206 of FIG. 5) to control the capacitance of the bank 218.

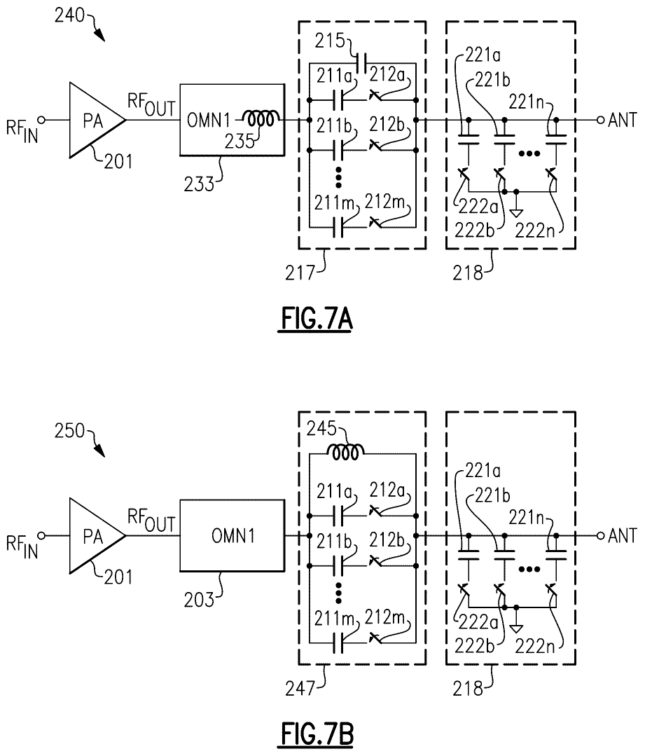

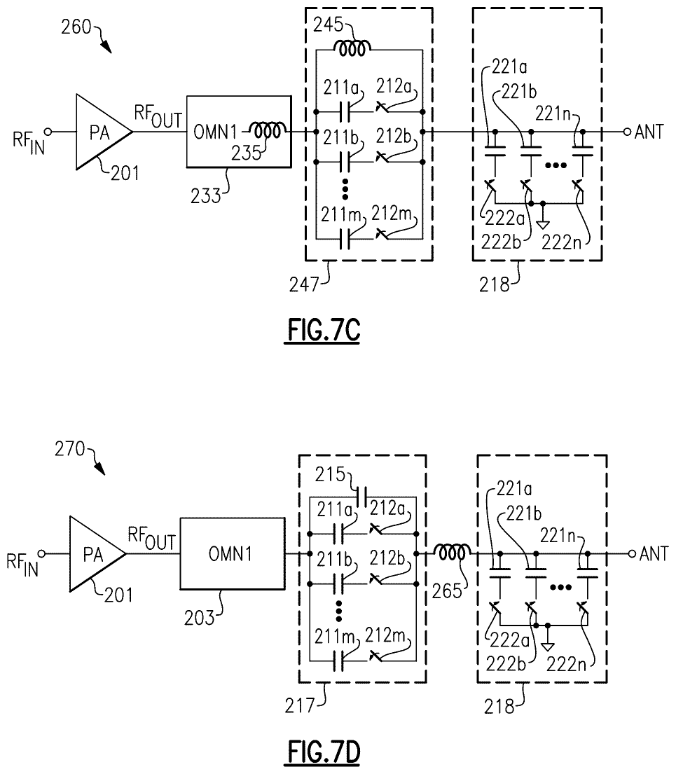

FIG. 7A is a schematic diagram of another embodiment of a power amplifier system 240 with load mismatch compensation. The power amplifier system 240 includes a power amplifier 201, a first output matching network 233, and a mismatch compensation circuit/second output matching network that includes a bank of switchable series capacitors 217 and a bank of switchable shunt capacitors 218. The power amplifier 201 amplifies an RF input signal RF_{IN} to generate an RF output signal RF_{OUT} that is provided to an antenna along an RF signal path that includes the first output matching network 233, the bank of switchable series capacitors 217, and the bank of switchable shunt capacitors 218.

The power amplifier system 240 of FIG. 7A is similar to the power amplifier system 230 of FIG. 6, except that the power amplifier system 240 includes a different implementation of the first output matching network 233. For example, the first output matching network 233 includes a series inductor 235 that is connected along the RF signal path at the output of the first output matching network 233.

A power amplifier system with mismatch compensation can include an inductor in series along the RF signal path in a wide variety of locations. Thus, although one example placement of the series inductor 235 is shown, other implementations are possible.

FIG. 7B is a schematic diagram of another embodiment of a power amplifier system 250 with load mismatch compensation. The power amplifier system 250 includes a power amplifier 201, a first output matching network 203, and a mismatch compensation circuit/second output matching network that includes a bank of switchable series capacitors 247 and a bank of switchable shunt capacitors 218. The power amplifier 201 amplifies an RF input signal RF_{IN} to generate an RF output signal RF_{OUT} that is provided to an antenna along an RF signal path that includes the first output matching network 203, the bank of switchable series capacitors 247, and the bank of switchable shunt capacitors 218.

The power amplifier system 250 of FIG. 7B is similar to the power amplifier system 230 of FIG. 6, except that the power amplifier system 250 includes a different implementation of the bank of switchable series capacitors 247. For example, in the embodiment of FIG. 7B, the fixed capacitor 215 has been omitted in favor of including a series inductor 245.

FIG. 7C is a schematic diagram of another embodiment of a power amplifier system 260 with load mismatch compensation. The power amplifier system 260 includes a power amplifier 201, a first output matching network 233, and a mismatch compensation circuit/second output matching network that includes a bank of switchable series capacitors 247 and a bank of switchable shunt capacitors 218. The power amplifier 201 amplifies an RF input signal RF_{IN} to generate an RF output signal RF_{OUT} that is provided to an antenna along an RF signal path that includes the first output matching network 233, the bank of switchable series capacitors 247, and the bank of switchable shunt capacitors 218.

The power amplifier system 260 of FIG. 7C is similar to the power amplifier system 250 of FIG. 7B, except that the power amplifier system 260 includes the output matching network 233 of FIG. 7A. Thus, the power amplifier system 260 of FIG. 7C includes two series inductors, in this embodiment. For instance, the first series inductor 235 is included at the output of the first matching network 233 while the second series inductor 245 is included in the bank of switchable series capacitors 247.

Any of the power amplifier systems herein can include multiple series inductors.

FIG. 7D is a schematic diagram of another embodiment of a power amplifier system 270 with load mismatch compensation. The power amplifier system 270 includes a power amplifier 201, a first output matching network 203, and a mismatch compensation circuit/second output matching network that includes a bank of switchable series capacitors 217, a series inductor 265, and a bank of switchable shunt capacitors 218. The power amplifier 201 amplifies an RF input signal RF_{IN} to generate an RF output signal RF_{OUT} that is provided to an antenna along an RF signal path that includes the first output matching network 203, the bank of switchable series capacitors 217, the series inductor 265, and the bank of switchable shunt capacitors 218.

The power amplifier system 270 of FIG. 7D is similar to the power amplifier system 230 of FIG. 6, except that the power amplifier system 270 further includes the series inductor 265 between the bank of switchable series capacitors 217 and the bank of switchable shunt capacitors 218.

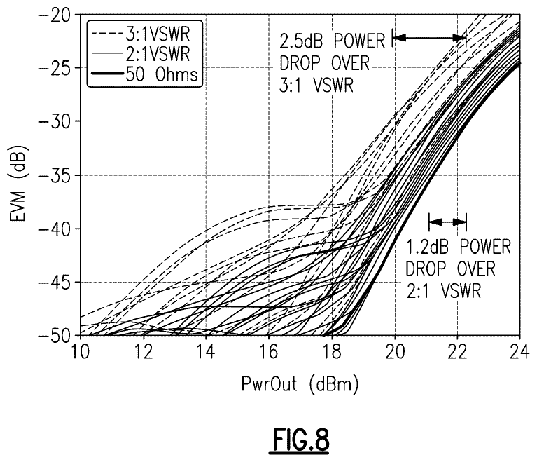

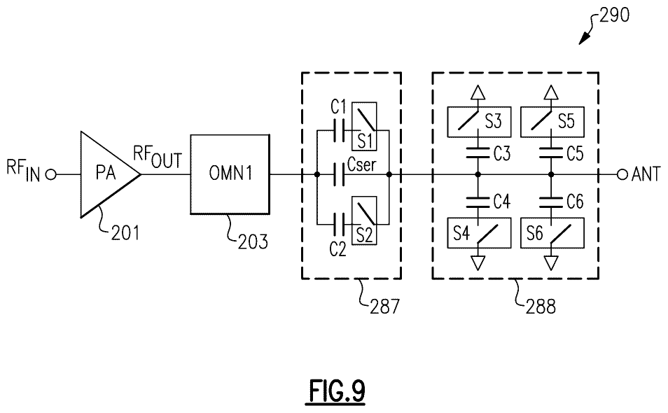

FIG. 8 is a graph of plots of EVM versus output power for various examples of power amplifier load mismatch. The plots include mismatch for 3:1 VSWR and 2:1 VSWR as compared to a 50Ω baseline. The plots are depicted for a simulated for one implementation of a Wi-Fi power amplifier operating at 2.5 GHz.

As shown in FIG. 8, the delivered output power drops by 2.5 dB at worst case 3:1 VSWR phase. This implies that the power amplifier would need to be oversized by 2.5 dB to meet a specification over 3:1 VSWR. However, oversizing a power amplifier results in a significant current consumption penalty and/or gain penalty.

FIG. 9 is a schematic diagram of another embodiment of a power amplifier system 290 with load mismatch compensation. The power amplifier system 290 includes a power amplifier 201, a first output matching network 203, and a mismatch compensation circuit/second output matching network that includes a bank of switchable series capacitors 287 and a bank of switchable shunt capacitors 288. The power amplifier 201 amplifies an RF input signal RF_{IN} to generate an RF output signal RF_{OUT} that is provided to an antenna along an RF signal path that includes the first output matching network 203, the bank of switchable series capacitors 287, and the bank of switchable shunt capacitors 288.

The power amplifier system 290 of FIG. 9 is similar to the power amplifier system 230 of FIG. 6, except that the power amplifier system 290 includes a different implementation of the bank of switchable series capacitors 287 and the bank of switchable shunt capacitors 288.

In the illustrated embodiment, the bank of switchable series capacitors 287 includes a series capacitor Cser in parallel with a first circuit branch and a second circuit branch. The first circuit branch includes a first capacitor C1 in series with a first switch S1, and the second circuit branch includes a second capacitor C2 in series with a second switch S2.

With continuing reference to FIG. 9, the bank of switchable shunt capacitors 288 includes a third circuit branch, a fourth circuit branch, a fifth circuit branch, and a sixth circuit branch each in parallel with one another between the RF signal path and ground. The third circuit branch includes a third capacitor C3 in series with a third switch S3, and the fourth circuit branch includes a fourth capacitor C4 in series with a fourth switch S4. Additionally, the fifth circuit branch includes a fifth capacitor C5 in series with a fifth switch S5, and the sixth circuit branch includes a sixth capacitor C6 in series with a fourth switch S6.

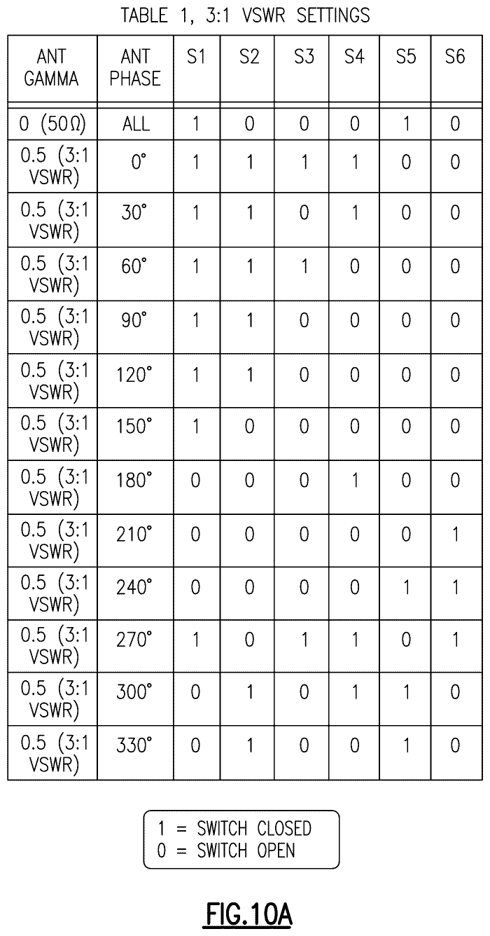

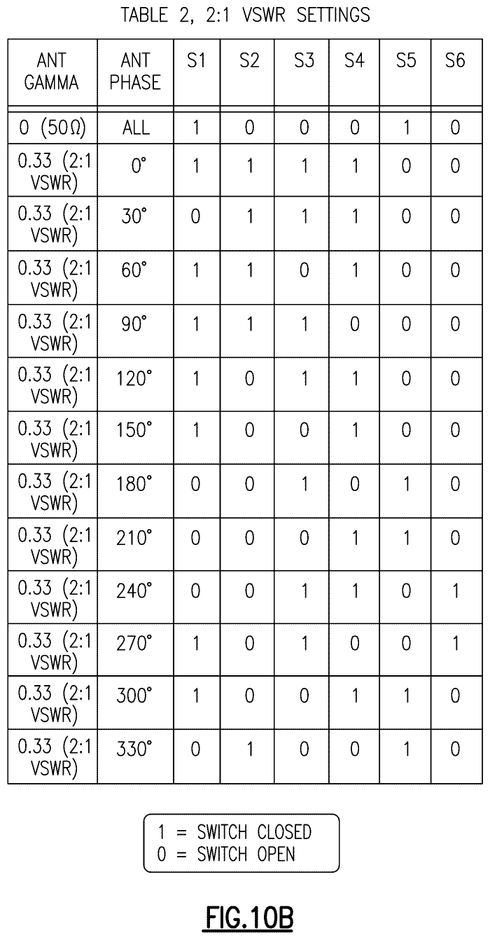

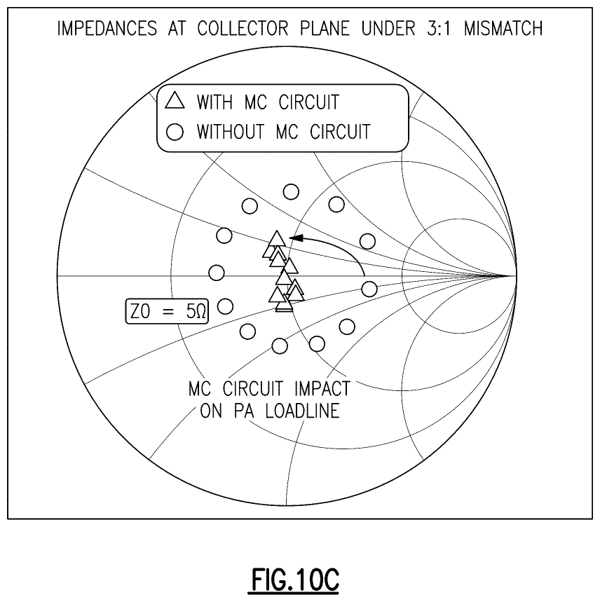

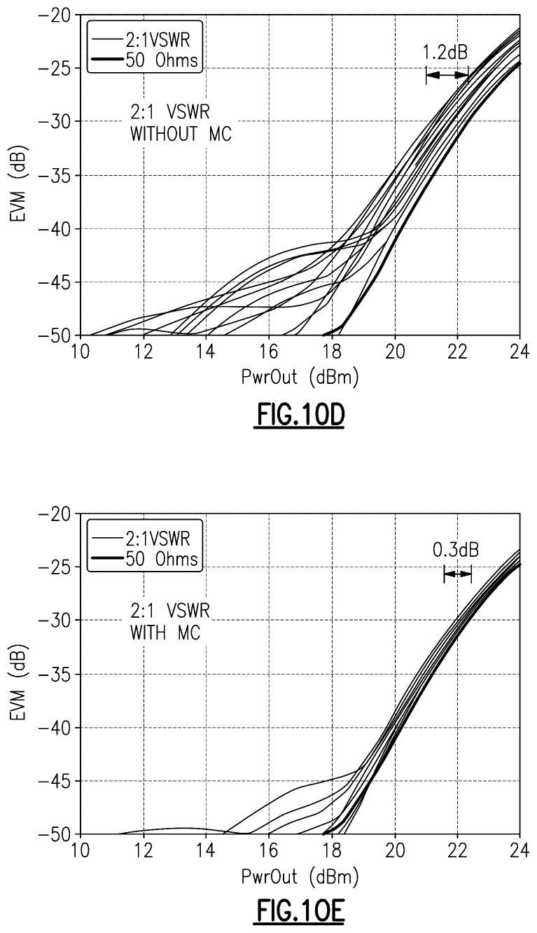

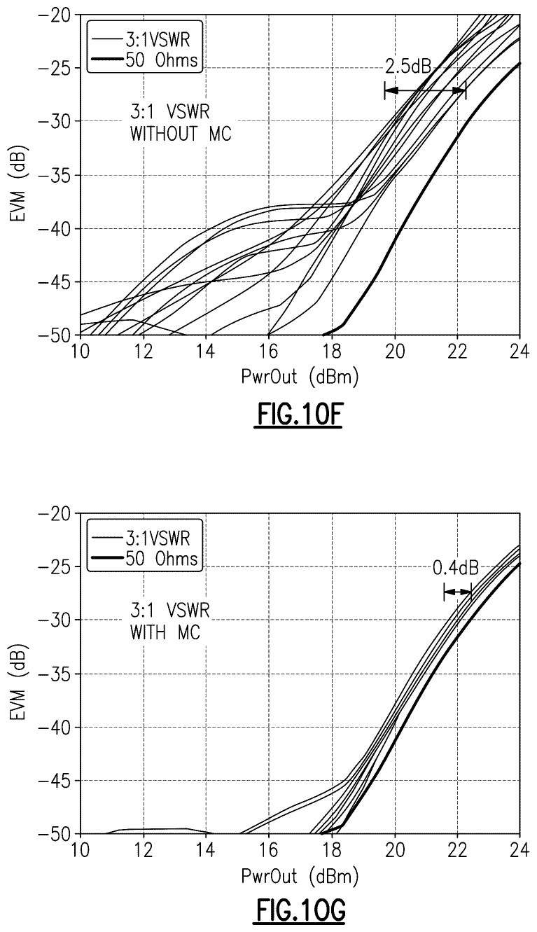

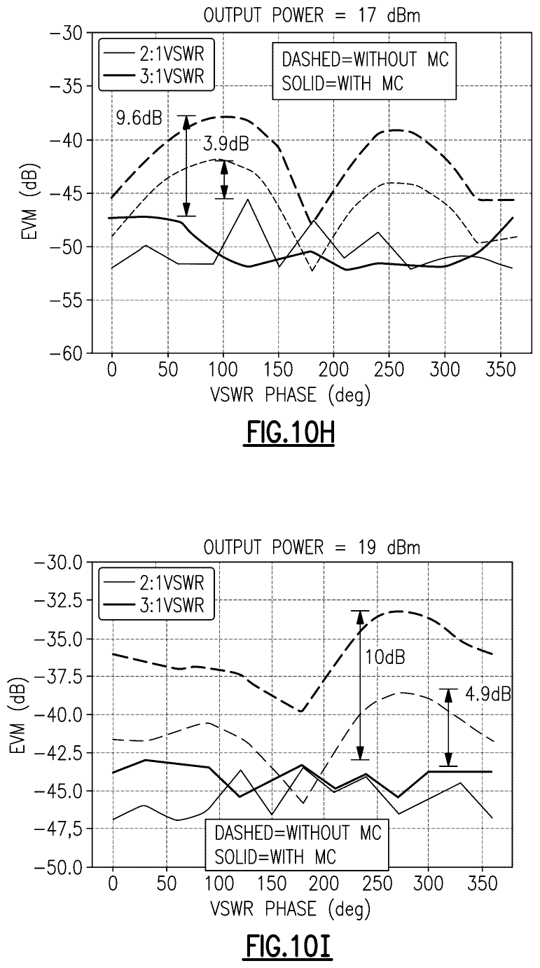

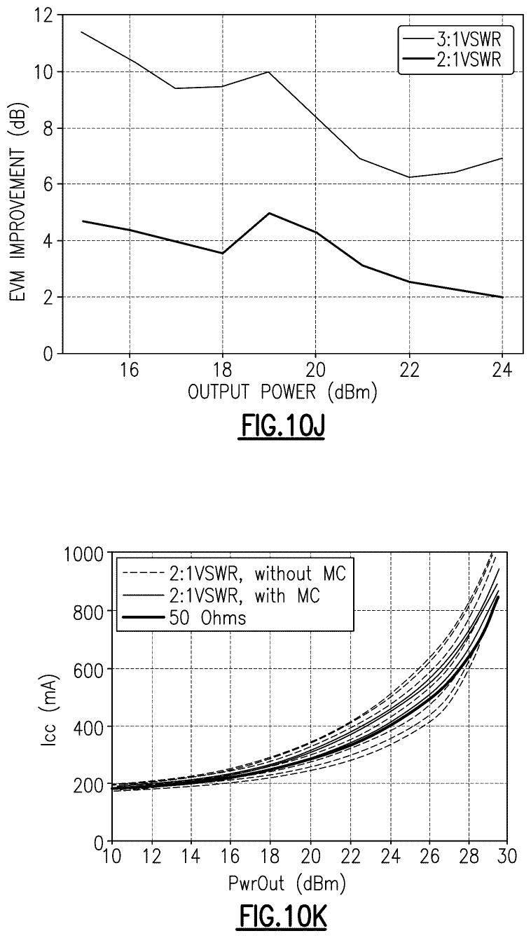

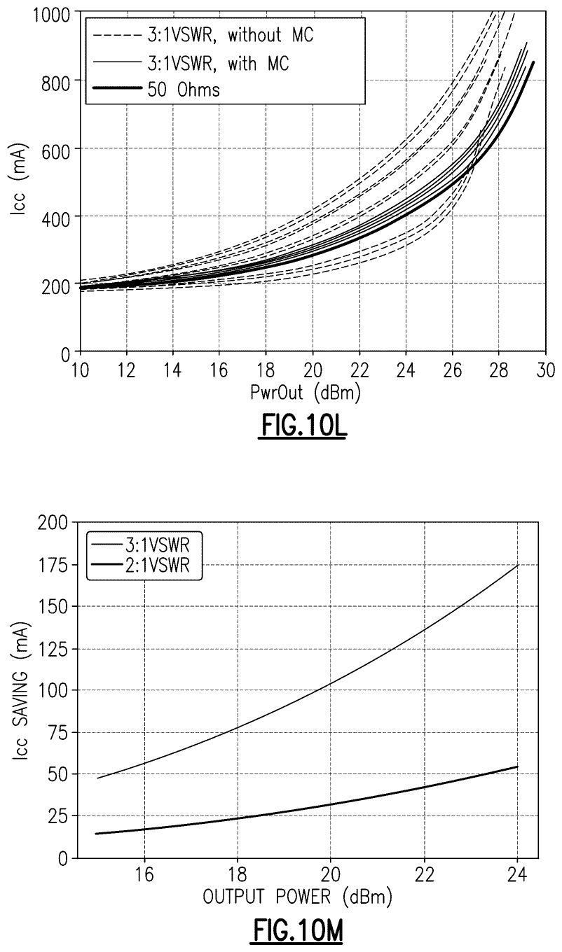

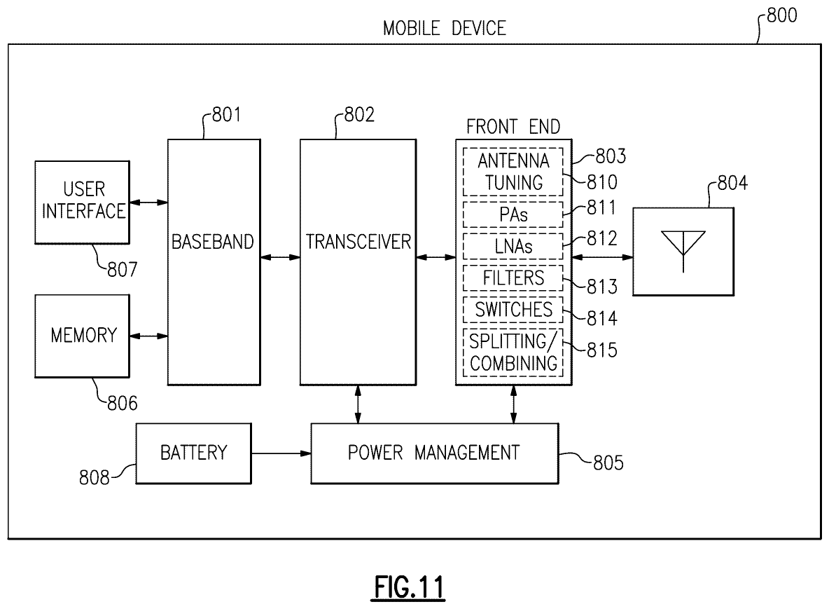

With general reference to FIGS. 10A-10G, simulation results for one implementation of a power amplifier operating at 2.5 GHz are shown. Certain results compare the power amplifier's operation with and without mismatch compensation. The mismatch compensation corresponds to one implementation of the mismatch compensation circuit of FIG. 9 in which Cser is 2.6 pF, C1 is 2 pF, C2 is 12 pF, C3 is 0.5 pF, C4 is 0.8 pF, C5 is 1.4 pF, and C6 is 2.2 pF.

FIG. 10A is a table of one example of mismatch compensation settings for the power amplifier system of FIG. 9 for 3:1 variation in VSWR. The table depicts antenna gamma and phase values and corresponding settings of each of the switches S1-S6, where 1 indicates that a particular switch is closed (turned on) and 0 indicates that the switch is open (turned off).

FIG. 10B is a table of one example of mismatch compensation settings for the power amplifier system of FIG. 9 for 2:1 variation in VSWR. The table depicts antenna gamma and phase values and corresponding settings of each of the switches S1-S6, where 1 indicates that a particular switch is closed and 0 indicates that the switch is open.

FIG. 10C is a Smith chart depicting example impedances at a collector of a bipolar transistor of a power amplifier for 3:1 variation in VSWR with and without mismatch compensation. The Smith chart shows that the mismatch compensation settings (corresponding to the switch settings of FIG. 10A, in this example) compensate for the load mismatch.

FIG. 10D is a graph of one example of EVM versus output power for one example of 2:1 variation in VSWR without mismatch compensation.

FIG. 10E is a graph of one example of EVM versus output power for one example of 2:1 variation in VSWR with mismatch compensation.

FIG. 10F is a graph of one example of EVM versus output power for one example of 3:1 variation in VSWR without mismatch compensation.

FIG. 10G is a graph of one example of EVM versus output power for one example of 3:1 variation in VSWR with mismatch compensation.

With reference to FIGS. 10D-10G, load mismatch compensation provides a vast improvement in output power at worst-case condition over VSWR. Furthermore, the mismatch compensation is highly effective for both 2:1 VSWR and 3:1 VSWR.

FIG. 10H is a graph of EVM versus VSWR phase at 17 dBm output power with and without mismatch compensation.

FIG. 10I is a graph of EVM versus VSWR phase at 19 dBm output power with and without mismatch compensation.

FIG. 10J is a graph of one example of EVM improvement from mismatch compensation versus output power.

With reference to FIGS. 10H-10J, load mismatch compensation provides a large EVM improvement over VSWR for the simulated output powers of interest. Furthermore, the mismatch compensation is highly effective for both 2:1 VSWR and 3:1 VSWR.

FIG. 10K is a graph of one example of collector current of a bipolar transistor of a power amplifier versus output power for 2:1 variation in VSWR with and without mismatch compensation.

FIG. 10L is a graph of one example of collector current of a bipolar transistor of a power amplifier versus output power for 3:1 variation in VSWR with and without mismatch compensation.

FIG. 10M is a graph of one example of collector current savings from mismatch compensation versus output power for 2:1 and 3:1 variation in VSWR.

With reference to FIGS. 10K-10M, load mismatch compensation provides a large current saving that increases with the magnitude of VSWR.

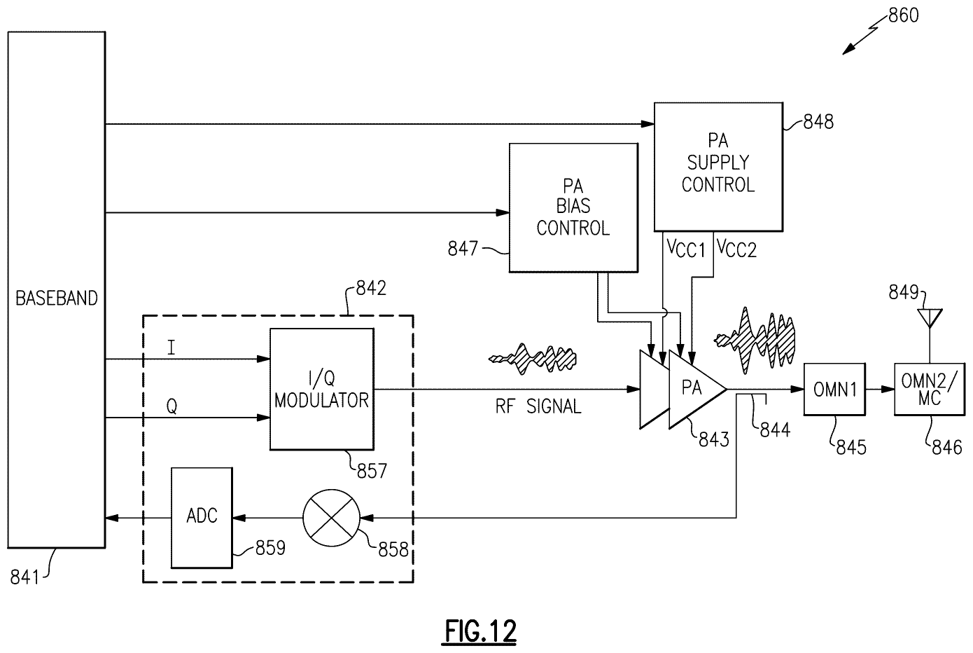

FIG. 11 is a schematic diagram of one embodiment of a mobile device 800. The mobile device 800 includes a baseband system 801, a transceiver 802, a front end system 803, antennas 804, a power management system 805, a memory 806, a user interface 807, and a battery 808.

The mobile device 800 can be used communicate using a wide variety of communications technologies, including, but not limited to, 2G, 3G, 4G (including LTE, LTE-Advanced, and LTE-Advanced Pro), 5G NR, WLAN (for instance, WiFi), WPAN (for instance, Bluetooth and ZigBee), WMAN (for instance, WiMax), and/or GPS technologies.

The transceiver 802 generates RF signals for transmission and processes incoming RF signals received from the antennas 804. It will be understood that various functionalities associated with the transmission and receiving of RF signals can be achieved by one or more components that are collectively represented in FIG. 11 as the transceiver 802. In one example, separate components (for instance, separate circuits or dies) can be provided for handling certain types of RF signals.

The front end system 803 aids in conditioning signals transmitted to and/or received from the antennas 804. In the illustrated embodiment, the front end system 803 includes antenna tuning circuitry 810, power amplifiers (PAs) 811, low noise amplifiers (LNAs) 812, filters 813, switches 814, and signal splitting/combining circuitry 815. However, other implementations are possible. The power amplifiers 812 can include one or more power amplifiers implemented with load mismatch compensation in accordance with the teachings herein.

The front end system 803 can provide a number of functionalities, including, but not limited to, amplifying signals for transmission, amplifying received signals, filtering signals, switching between different bands, switching between different power modes, switching between transmission and receiving modes, duplexing of signals, multiplexing of signals (for instance, diplexing or triplexing), or some combination thereof.

In certain implementations, the mobile device 800 supports carrier aggregation, thereby providing flexibility to increase peak data rates. Carrier aggregation can be used for both Frequency Division Duplexing (FDD) and Time Division Duplexing (TDD), and may be used to aggregate a plurality of carriers or channels. Carrier aggregation includes contiguous aggregation, in which contiguous carriers within the same operating frequency band are aggregated. Carrier aggregation can also be non-contiguous, and can include carriers separated in frequency within a common band or in different bands.

The antennas 804 can include antennas used for a wide variety of types of communications. For example, the antennas 804 can include antennas for transmitting and/or receiving signals associated with a wide variety of frequencies and communications standards.

In certain implementations, the antennas 804 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The mobile device 800 can operate with beamforming in certain implementations. For example, the front end system 803 can include amplifiers having controllable gain and phase shifters having controllable phase to provide beam formation and directivity for transmission and/or reception of signals using the antennas 804. For example, in the context of signal transmission, the amplitude and phases of the transmit signals provided to the antennas 804 are controlled such that radiated signals from the antennas 804 combine using constructive and destructive interference to generate an aggregate transmit signal exhibiting beam-like qualities with more signal strength propagating in a given direction. In the context of signal reception, the amplitude and phases are controlled such that more signal energy is received when the signal is arriving to the antennas 804 from a particular direction. In certain implementations, the antennas 804 include one or more arrays of antenna elements to enhance beamforming.

The baseband system 801 is coupled to the user interface 807 to facilitate processing of various user input and output (I/O), such as voice and data. The baseband system 801 provides the transceiver 802 with digital representations of transmit signals, which the transceiver 802 processes to generate RF signals for transmission. The baseband system 801 also processes digital representations of received signals provided by the transceiver 802. As shown in FIG. 11, the baseband system 801 is coupled to the memory 806 of facilitate operation of the mobile device 800.

The memory 806 can be used for a wide variety of purposes, such as storing data and/or instructions to facilitate the operation of the mobile device 800 and/or to provide storage of user information.

The power management system 805 provides a number of power management functions of the mobile device 800. In certain implementations, the power management system 805 includes a PA supply control circuit that controls the supply voltages of the power amplifiers 811. For example, the power management system 805 can be configured to change the supply voltage(s) provided to one or more of the power amplifiers 811 to improve efficiency, such as power added efficiency (PAE).

As shown in FIG. 11, the power management system 805 receives a battery voltage from the battery 808. The battery 808 can be any suitable battery for use in the mobile device 800, including, for example, a lithium-ion battery.

FIG. 12 is a schematic diagram of a power amplifier system 860 according to one embodiment. The illustrated power amplifier system 860 includes a baseband processor 841, a transmitter/observation receiver 842, a power amplifier (PA) 843, a directional coupler 844, a first output matching network 845, a second output matching network/mismatch compensation circuit 846, a PA bias control circuit 847, a PA supply control circuit 848, and an antenna 849. The illustrated transmitter/observation receiver 842 includes an I/Q modulator 857, a mixer 858, and an analog-to-digital converter (ADC) 859. In certain implementations, the transmitter/observation receiver 842 is incorporated into a transceiver.

The baseband processor 841 can be used to generate an in-phase (I) signal and a quadrature-phase (Q) signal, which can be used to represent a sinusoidal wave or signal of a desired amplitude, frequency, and phase. For example, the I signal can be used to represent an in-phase component of the sinusoidal wave and the Q signal can be used to represent a quadrature-phase component of the sinusoidal wave, which can be an equivalent representation of the sinusoidal wave. In certain implementations, the I and Q signals can be provided to the I/Q modulator 857 in a digital format. The baseband processor 841 can be any suitable processor configured to process a baseband signal. For instance, the baseband processor 841 can include a digital signal processor, a microprocessor, a programmable core, or any combination thereof. Moreover, in some implementations, two or more baseband processors 841 can be included in the power amplifier system 860.

The I/Q modulator 857 can be configured to receive the I and Q signals from the baseband processor 841 and to process the I and Q signals to generate an RF signal. For example, the I/Q modulator 857 can include digital-to-analog converters (DACs) configured to convert the I and Q signals into an analog format, mixers for upconverting the I and Q signals to RF, and a signal combiner for combining the upconverted I and Q signals into an RF signal suitable for amplification by the power amplifier 843. In certain implementations, the I/Q modulator 857 can include one or more filters configured to filter frequency content of signals processed therein.

The power amplifier 843 can receive the RF signal from the I/Q modulator 857, and when enabled can provide an amplified RF signal to the antenna 849 via the first output matching network 845 and the second output matching network/mismatch compensation circuit 846.

Although FIG. 12 depicts the second output matching network/mismatch compensation circuit 846 as being directly connected to the antenna 849, in other implementations one or more switches, filters, duplexers, multiplexers, and/or other components are included between the second output matching network/mismatch compensation circuit 846 and the antenna 849.

The directional coupler 844 senses an output signal of the power amplifier 823. Additionally, the sensed output signal from the directional coupler 844 is provided to the mixer 858, which multiplies the sensed output signal by a reference signal of a controlled frequency. The mixer 858 operates to generate a downshifted signal by downshifting the sensed output signal's frequency content. The downshifted signal can be provided to the ADC 859, which can convert the downshifted signal to a digital format suitable for processing by the baseband processor 841. Including a feedback path from the output of the power amplifier 843 to the baseband processor 841 can provide a number of advantages. For example, implementing the baseband processor 841 in this manner can aid in providing power control, compensating for transmitter impairments, and/or in performing digital pre-distortion (DPD). Although one example of a sensing path for a power amplifier is shown, other implementations are possible.

The PA supply control circuit 848 receives a power control signal from the baseband processor 841, and controls supply voltages of the power amplifier 843. In the illustrated configuration, the PA supply control circuit 848 generates a first supply voltage V_{CC1} for powering an input stage of the power amplifier 843 and a second supply voltage V_{CC2} for powering an output stage of the power amplifier 843. The PA supply control circuit 848 can control the voltage level of the first supply voltage V_{CC1} and/or the second supply voltage V_{CC2} to enhance the power amplifier system's PAE.

The PA supply control circuit 848 can employ various power management techniques to change the voltage level of one or more of the supply voltages over time to improve the power amplifier's power added efficiency (PAE), thereby reducing power dissipation.

One technique for improving efficiency of a power amplifier is average power tracking (APT), in which a DC-to-DC converter is used to generate a supply voltage for a power amplifier based on the power amplifier's average output power. Another technique for improving efficiency of a power amplifier is envelope tracking (ET), in which a supply voltage of the power amplifier is controlled in relation to the envelope of the RF signal. Thus, when a voltage level of the envelope of the RF signal increases the voltage level of the power amplifier's supply voltage can be increased. Likewise, when the voltage level of the envelope of the RF signal decreases the voltage level of the power amplifier's supply voltage can be decreased to reduce power consumption.

In certain configurations, the PA supply control circuit 848 is a multi-mode supply control circuit that can operate in multiple supply control modes including an APT mode and an ET mode. For example, the power control signal from the baseband processor 841 can instruct the PA supply control circuit 848 to operate in a particular supply control mode.

As shown in FIG. 12, the PA bias control circuit 847 receives a bias control signal from the baseband processor 841 and generates bias control signals for the power amplifier 843. In the illustrated configuration, the bias control circuit 847 generates bias control signals for both an input stage of the power amplifier 843 and an output stage of the power amplifier 843. However, other implementations are possible.

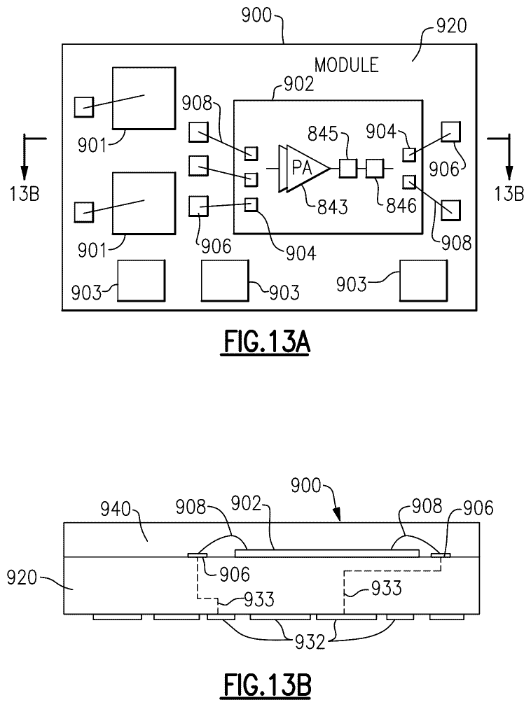

FIG. 13A is a schematic diagram of one embodiment of a packaged module 900. FIG. 13B is a schematic diagram of a cross-section of the packaged module 900 of FIG. 13A taken along the lines 13B-13B.

The packaged module 900 includes radio frequency component(s) 901, semiconductor die(s) 902, surface mount device(s) 903, bond wire(s) 908, a package substrate 920, and an encapsulation structure 940. The package substrate 920 includes pad(s) 906 formed from conductors disposed therein. Additionally, the semiconductor die(s) 902 include pin(s) or pad(s) 904, and the bond wire(s) 908 have been used to connect the pad(s) 904 of the die(s) 902 to the pad(s) 906 of the package substrate 920.

The semiconductor die(s) 902 include a power amplifier 843, a first output matching network 845, and a second output matching network/mismatch compensation circuit 846, which can be implemented in accordance with one or more features disclosed herein. Such components can be formed on a single die or on multiple dies. In one example, the power amplifier 843 is formed on a compound semiconductor die (for instance, a GaAs die), while the switches used for controlling mismatch compensation are formed on a silicon die (for instance, a silicon-on-insulator die).

The packaging substrate 920 can be configured to receive a plurality of components such as radio frequency component(s) 901, the semiconductor die(s) 902 and the surface mount device(s) 903, which can include, for example, surface mount capacitor(s) and/or inductor(s). In one implementation, the radio frequency component(s) 901 include one or more integrated passive devices (IPDs).

As shown in FIG. 13B, the packaged module 900 is shown to include a plurality of contact pad(s) 932 disposed on the side of the packaged module 900 opposite the side used to mount the semiconductor die(s) 902. Configuring the packaged module 900 in this manner can aid in connecting the packaged module 900 to a circuit board, such as a phone board of a mobile device. The example contact pad(s) 932 can be configured to provide radio frequency signals, bias signals, and/or power (for example, a power supply voltage and ground) to the semiconductor die(s) 902 and/or other components. As shown in FIG. 12B, the electrical connections between the contact pad(s) 932 and the semiconductor die(s) 902 can be facilitated by connection(s) 933 through the package substrate 920. The connection(s) 933 can represent electrical paths formed through the package substrate 920, such as connections associated with vias and conductors of a multilayer laminated package substrate.

In some embodiments, the packaged module 900 can also include one or more packaging structures to, for example, provide protection and/or facilitate handling. Such a packaging structure can include overmold or encapsulation structure 940 formed over the packaging substrate 920 and the components and die(s) disposed thereon.

It will be understood that although the packaged module 900 is described in the context of electrical connections based on wirebonds, one or more features of the present disclosure can also be implemented in other packaging configurations, including, for example, flip-chip configurations.

### Applications

The principles and advantages of the embodiments herein can be used for any other systems or apparatus that have needs for power amplifiers. Examples of such apparatus include RF communication systems. RF communications systems include, but are not limited to, mobile phones, tablets, base stations, network access points, customer-premises equipment (CPE), laptops, and wearable electronics. Thus, the power amplifiers herein can be included in various electronic devices, including, but not limited to, consumer electronic products.

### CONCLUSION

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “may,” “could,” “might,” “can,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While certain embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

1. A power amplifier system comprising:
a power amplifier having an input configured to receive a radio frequency input signal and an output configured to provide a radio frequency output signal;
an antenna terminal configured to electrically connect to an antenna; and
a mismatch compensation circuit electrically connected along a radio frequency signal path from the output of the power amplifier to the antenna terminal, the mismatch compensation circuit including a bank of switchable shunt capacitors and a bank of switchable series capacitors that is electrically connected between the output of the power amplifier and the bank of switchable shunt capacitors.

2. The power amplifier system of claim 1 wherein the bank of switchable series capacitors includes a first circuit branch in parallel with a second circuit branch between the output of the power amplifier and the antenna terminal, the first circuit branch including a first capacitor in series with a first switch and the second circuit branch including a second capacitor in series with a second switch.

3. The power amplifier system of claim 2 wherein the bank of switchable shunt capacitors includes a third circuit branch and a fourth circuit branch each connected between the radio frequency signal path and a ground voltage, the third circuit branch including a third capacitor in series with a third switch and the fourth circuit branch including a fourth capacitor in series with a fourth switch.

4. The power amplifier system of claim 3 wherein the bank of switchable shunt capacitors further includes a fifth circuit branch electrically connected between the radio frequency signal path and the ground voltage and a sixth circuit branch electrically connected between the radio frequency signal path and the ground voltage, the third circuit branch including a fifth capacitor in series with a fifth switch and the sixth circuit branch including a sixth capacitor in series with a sixth switch.

5. The power amplifier system of claim 3 wherein the bank of switchable series capacitors further includes a capacitor in parallel with the first circuit branch and the second circuit branch.

6. The power amplifier system of claim 3 wherein the bank of switchable series capacitors further includes an inductor parallel with the first circuit branch and the second circuit branch.

7. The power amplifier system of claim 1 further comprising a first output matching network electrically connected between the output of the power amplifier and the bank of switchable series capacitors.

8. The power amplifier system of claim 7 wherein the first output matching network includes an output connected to the bank of switchable series capacitors and a series inductor at the output.

9. The power amplifier system of claim 1 wherein the mismatch compensation circuit further includes an inductor electrically connected between the bank of switchable series capacitors and the bank of switchable shunt capacitors.

10. A mobile device comprising:
an antenna; and
a front-end system including a power amplifier configured to receive a radio frequency input signal at an input and to provide a radio frequency output signal at an output, the front-end system further including a mismatch compensation circuit electrically connected along a radio frequency signal path from the output of the power amplifier to the antenna, the mismatch compensation circuit including a bank of switchable shunt capacitors and a bank of switchable series capacitors that is electrically connected between the output of the power amplifier and the bank of switchable shunt capacitors.

11. The mobile device of claim 10 wherein the bank of switchable series capacitors includes a first circuit branch in parallel with a second circuit branch between the output of the power amplifier and the antenna, the first circuit branch including a first capacitor in series with a first switch and the second circuit branch including a second capacitor in series with a second switch.

12. The mobile device of claim 11 wherein the bank of switchable shunt capacitors includes a third circuit branch and a fourth circuit branch each connected between the radio frequency signal path and a ground voltage, the third circuit branch including a third capacitor in series with a third switch and the fourth circuit branch including a fourth capacitor in series with a fourth switch.

13. The mobile device of claim 12 wherein the bank of switchable shunt capacitors further includes a fifth circuit branch electrically connected between the radio frequency signal path and the ground voltage and a sixth circuit branch electrically connected between the radio frequency signal path and the ground voltage, the fifth circuit branch including a fifth capacitor in series with a fifth switch and the sixth circuit branch including a sixth capacitor in series with a sixth switch.

14. The mobile device of claim 12 wherein the bank of switchable series capacitors further includes a capacitor in parallel with the first circuit branch and the second circuit branch.

15. The mobile device of claim 12 wherein the bank of switchable series capacitors further includes an inductor parallel with the first circuit branch and the second circuit branch.

16. The mobile device of claim 10 wherein the front-end system further includes a first output matching network electrically connected between the output of the power amplifier and the bank of switchable series capacitors.

17. The mobile device of claim 16 wherein the first output matching network includes an output connected to the bank of switchable series capacitors and a series inductor at the output.

18. The mobile device of claim 10 wherein the mismatch compensation circuit further includes an inductor electrically connected between the bank of switchable series capacitors and the bank of switchable shunt capacitors.

19. A packaged module comprising:
a package substrate; and
one or more semiconductor dies attached to the package substrate, the one or more semiconductor dies including a power amplifier configured to receive a radio frequency input signal at an input and to provide a radio frequency output signal at an output, the one or more semiconductor dies further including a mismatch compensation circuit electrically connected along a radio frequency signal path from the output of the power amplifier to an antenna terminal, the mismatch compensation circuit including a bank of switchable shunt capacitors and a bank of switchable series capacitors that is electrically connected between the output of the power amplifier and the bank of switchable shunt capacitors.

20. The packaged module of claim 19 wherein the bank of switchable series capacitors includes a first circuit branch in parallel with a second circuit branch between the output of the power amplifier and the antenna terminal, the first circuit branch including a first capacitor in series with a first switch and the second circuit branch including a second capacitor in series with a second switch.

21.-58. (canceled)
